(19) United States
(12) Patent Application Publication
(10) Pub. No.: US 2025/0140542 A1
(43) Pub. Date: May 1, 2025

(54) EVALUATION OF PLASMA UNIFORMITY USING COMPUTER VISION

(71) Applicant: Lam Research Corporation, Fremont, CA (US)

(72) Inventors: Kapil Sawlani, Ann Arbor, MI (US); Paul Franzen, West Linn, OR (US); Oksana Savchak, Tualatin, OR (US); Michal Danek, Cupertino, CA (US); Karl Frederick Leeser, West Linn, OR (US); Samuel Tobin, Mountain View, CA (US)

(21) Appl. No.: 18/835,800

(22) PCT Filed: Feb. 3, 2023
(86) PCT No.: PCT/US2023/061947

§ 371 Date: Aug. 5, 2024

Related U.S. Application Data
(60) Provisional application No. 63/267,706, filed on Feb. 8, 2022.

(51) Int. Cl. H01J 37/32; H01L 21/66; H01L 21/67

(52) U.S. Cl. CPC H01J 37/3299; H01L 21/67253; H01L 22/20; H01J 2237/332

(57) ABSTRACT

Various embodiments herein relate to apparatuses and methods for evaluating plasma uniformity using computer vision. In some embodiments, a method comprises obtaining signals from one or more camera sensors optically coupled to one or more optical access apertures of a device fabrication process chamber during performance of a plasma-based operation. The method may comprise determining, from the signals, plasma characteristics during the performance of the plasma-based operation. The method may comprise determining, from the plasma characteristics, a non-uniformity of one or more wafer characteristics of a wafer undergoing the plasma-based operation.

### RELATED APPLICATIONS

A PCT Request Form is filed concurrently with this specification as part of the present application. Each application that the present application claims benefit of or priority to as identified in the concurrently filed PCT Request Form is incorporated by reference herein in its entirety.

### BACKGROUND

In complex semiconductor manufacturing processes, such as atomic layer deposition (ALD), chemical vapor deposition (CVD), etc., there may be drifts or shifts in the system that cause corresponding drifts or shifts in physical parameters of wafers undergoing processing. Typically, control of the system may utilize ex situ metrology, in which wafers that have undergone processing are subsequently analyzed, for example, to identify drifts or shifts in a tool in which the wafer was processed. However, ex situ techniques may be costly and time-consuming, because ex situ techniques may require separate standalone equipment to analyze wafers. Moreover, because wafers are typically analyzed post-processing, wafers may be wasted due to not identifying system drift in real-time.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor implicitly admitted as prior art against the present disclosure.

### SUMMARY

Disclosed herein are apparatuses and methods for evaluation of plasma uniformity using computer vision.

In some embodiments, a method is provided. The method may comprise: obtaining signals from one or more camera sensors optically coupled to one or more optical access apertures of a device fabrication process chamber during performance of a plasma-based operation; determining, from the signals, plasma characteristics during the performance of the plasma-based operation; and determining, from the plasma characteristics, a non-uniformity of one or more wafer characteristics of a wafer undergoing the plasma-based operation.

In some examples, the plasma characteristics comprise a metric indicative of plasma uniformity within a portion of the device fabrication process chamber.

In some examples, the plasma characteristics comprise a metric indicative of plasma location within a portion of the device fabrication process chamber and a metric indicative of an intensity of plasma at different portions of the device fabrication process chamber.

In some examples, the method further comprises determining a change that is to be made to one or more process conditions performed by the device fabrication process chamber. In some examples, the process conditions comprise: adjustments to a plasma source associated with the device fabrication process chamber, adjustments to a temperature associated with the device fabrication process chamber, adjustments to a composition of process gases associated with the device fabrication process chamber, or adjustments to flow rates of the process gases.

In some examples, the method further comprises: determining, during the plasma-based operation, a change that is to be made to a plasma source associated with the device fabrication process chamber based at least in part on the plasma characteristics; and causing the determined change to be made to the plasma source associated with the device fabrication process chamber. In some examples, the change to the plasma source comprises one or more of: a change to a coil position of a coil of the plasma source, a change in a current ratio delivered to two or more coils of the plasma source, or a change to gas flow parameters of one or more gases delivered to the plasma source.

In some examples, the method further comprises identifying at least one change to be made to the device fabrication process chamber after the plasma-based operation has been completed for the wafer undergoing fabrication based at least in part on the plasma characteristics.

In some examples, the method further comprises identifying at least one change that is to be made in a subsequent operation the wafer will undergo after completion of the plasma-based operation based at least in part on the plasma characteristics.

In some examples, the device fabrication process chamber comprises a multi-station fabrication tool, and wherein the wafer undergoing processing is residing in a first station of the multi-station fabrication tool. In some examples, the method further comprises processing the received signals to account for signals due to plasma in stations of the multi-station fabrication tool other than the first station. In some examples, processing the received signals to account for the signals due to plasma in the stations of the multi-station fabrication tool other than the first station comprises discarding pixels determined to be associated with the plasma in the stations other than the first station.

In some examples, determining the plasma characteristics comprises: identifying one or more plasma regions in a frame of camera data associated with the received signals; and determining the plasma characteristics for each of the one or more plasma regions. In some examples, the one or more plasma regions comprise a region proximate to a showerhead of the device fabrication process chamber or a pedestal of the device fabrication process chamber. In some examples, the one or more plasma regions are identified by performing edge detection on the frame of camera data. In some examples, the one or more plasma regions are identified by providing the frame of camera data to a neural network.

In some examples, the method further comprises triggering collection of signals by the one or more camera sensors via a trigger based on a synchronization of the trigger and plasma pulses of the plasma-based operation. In some examples, the trigger is configured to trigger collection of the signals such that at least about three (3) frames are captured by the one or more camera sensors for a single plasma pulse of the plasma pulses. In some examples, the method further comprises integrating received signals corresponding to the at least about three (3) frames over a duration of the single plasma pulse to determine the plasma characteristics.

In some examples, the non-uniformity of the one or more wafer characteristics are determined by providing the plasma characteristics to a machine learning model.

In some examples, the plasma-based operation is a deposition process. In some examples, the deposition process comprises: plasma-enhanced atomic layer deposition (PEALD), plasma-enhanced chemical vapor deposition (PECVD), or plasma-enhanced epitaxial growth.

In some embodiments, a system is provided. The system comprises: a process chamber configured to perform plasma-based operations on a wafer residing in the process chamber; one or more optical access apertures that provide optical access into the process chamber; one or more camera sensors optically coupled to the one or more optical access apertures; and a controller. The controller may be configured to: transmit signals from the one or more camera sensors during performance of a plasma-based operation to an edge device; obtain information from the edge device, the information indicative of plasma characteristics within the process chamber during performance of the plasma-based operation, wherein the plasma characteristics are indicative of a non-uniformity of one or more wafer characteristics of a wafer undergoing the plasma-based operation; and cause at least one change in process conditions to be implemented in the process chamber based at least in part on the plasma characteristics.

In some examples, the system further comprises one or more spectral filters configured to filter the signals from the one or more camera sensors based on wavelength.

In some examples, the system further comprises a plasma source, and wherein the at least one change in process conditions comprises a change to the plasma source. In some examples, the change to the plasma source comprises one or more of: a change to a coil position of a coil of the plasma source, a change in a current ratio delivered to two or more coils of the plasma source, or a change to gas flow parameters of one or more gases delivered to the plasma source.

In some examples, the process chamber comprises a showerhead, and wherein the at least one change comprises a change in at least one of a tilt or a vertical position of the showerhead.

In some examples, the process chamber comprises a multi-station fabrication tool, wherein the wafer is residing in a first station of the multi-station fabrication tool, and wherein the plasma characteristics received from the edge device account for plasma in other stations of the multi-station fabrication tool other than the first station.

In some examples, the controller is further configured to: cause a plasma pulse to occur in association with the process chamber; and cause the signals to be captured by the one or more camera sensors in a manner that is substantially synchronized with the plasma pulse.

### BRIEF DESCRIPTION OF THE DRAWINGS

FIG. 1 includes images that depict examples of wafer thickness non-uniformity.

FIG. 2A is a schematic diagram of an example apparatus in accordance with some embodiments.

FIG. 2B is a schematic diagram of an example multi-station tool in accordance with some embodiments.

FIG. 2C is a diagram that illustrates a field of view of a camera in connection with a multi-station tool in accordance with some embodiments.

FIG. 3 is a system block diagram of a system for evaluating plasma uniformity in accordance with some embodiments.

FIG. 4 is an example plot showing plasma intensity as a function of position in accordance with some embodiments.

FIGS. 5A, 5B, 5C, 5D, and 5E are example plots depicting a relationship between plasma intensity and wafer thickness in accordance with some embodiments.

FIG. 6 is a flowchart of an example process for determining plasma characteristics in accordance with some implementations.

FIG. 7 is a flowchart of an example process for making changes to a tool responsive to determined plasma characteristics in accordance with some embodiments.

FIGS. 8A and 8B includes example images corresponding to plasma associated with different stations of a multi-station tool from a single viewpoint.

FIG. 9 is a flowchart of an example process for processing images in accordance with some implementations.

FIG. 10 presents an example computer system that may be employed to implement certain embodiments described herein.

### DETAILED DESCRIPTION

### Terminology

The following terms are used throughout the instant specification:

The terms “semiconductor wafer,” “wafer,” “substrate,” “wafer substrate” and “partially fabricated integrated circuit” may be used interchangeably. Those of ordinary skill in the art understand that the term “partially fabricated integrated circuit” can refer to a semiconductor wafer during any of many stages of integrated circuit fabrication thereon. A wafer or substrate used in the semiconductor device industry typically has a diameter of 200 mm, or 300 mm, or 450 mm. Besides semiconductor wafers, other work pieces that may take advantage of the disclosed embodiments include various articles such as printed circuit boards, magnetic recording media, magnetic recording sensors, mirrors, optical elements, display devices or components such as backplanes for pixelated display devices, flat-panel displays, micro-mechanical devices and the like. The work piece may be of various shapes, sizes, and materials.

A “semiconductor device fabrication operation” as used herein is an operation performed during fabrication of semiconductor devices. Typically, the overall fabrication process includes multiple semiconductor device fabrication operations, each performed in its own semiconductor fabrication tool such as a plasma reactor, an electroplating cell, a chemical mechanical planarization tool, a wet etch tool, and the like. Categories of semiconductor device fabrication operations include subtractive processes, such as etch processes and planarization processes, and material additive processes, such as deposition processes (e.g., physical vapor deposition, chemical vapor deposition, atomic layer deposition, electrochemical deposition, electroless deposition). In the context of etch processes, a substrate etch process includes processes that etch a mask layer or, more generally, processes that etch any layer of material previously deposited on and/or otherwise residing on a substrate surface. Such an etch process may etch a stack of layers in the substrate.

“Manufacturing equipment” refers to equipment in which a manufacturing process takes place. Manufacturing equipment often has a process chamber in which the workpiece resides during processing. Typically, when in use, manufacturing equipment performs one or more semiconductor device fabrication operations. Examples of manufacturing equipment for semiconductor device fabrication include deposition reactors such as electroplating cells, physical vapor deposition reactors, chemical vapor deposition reactors, and atomic layer deposition reactors, and subtractive process reactors such as dry etch reactors (e.g., chemical and/or physical etch reactors), wet etch reactors, and ashers.

### Evaluation of Plasma Uniformity

To maximize production in semiconductor fabrication, it is necessary to increase product yields by minimizing the number of fabricated wafers that must be discarded for not meeting specifications. For many fabrication processes, such as atomic layer deposition (ALD), atomic layer etch (ALE), chemical vapor deposition (CVD), plasma-enhanced chemical vapor deposition (PECVD), or the like, there are numerous process parameters that may need to be carefully controlled to account for system drift or shift, variations in components of the tool, or the like. In some cases, ex situ metrology may be used to identify system drift or shift, and therefore, changes to process parameters to be implemented to control wafer quality. However, because ex situ metrology is performed after wafer fabrication, and because ex situ metrology requires additional tools that are relatively expensive to utilize, use of ex situ metrology does not allow for run-time control of a tool. Moreover, because ex situ metrology may be expensive to utilize, it is difficult to utilize ex situ metrology to improve product yield. For example, due to the expense, equipment for performing ex situ metrology may be limited, accordingly, it is not possible to perform ex situ metrology on all wafers. Moreover, performing ex situ metrology on more wafers decreases overall fabrication throughput.

It is important for wafer characteristics of a wafer that has undergone processing to meet specifications. One example of a wafer characteristic that may be crucial to conform to a specification is wafer thickness resulting from a deposition process. In cases in which such a deposition process is a plasma-based deposition operation (e.g., PECVD), wafer thickness may be correlated with plasma intensity. For example, higher plasma intensities in a particular region of a station or process chamber may correlate with reduced wafer thickness in the corresponding region. Moreover, non-uniformity of plasma within the station or process chamber may lead to non-uniformities of the wafer, which is undesirable. As used herein, “non-uniformity” of wafer characteristics generally refers to variations across the wafer, for example, of a thickness of a deposited layer or a thickness of an etched layer.

Described herein are techniques for utilizing computer vision to determine plasma characteristics and utilizing the plasma characteristics to control one or more fabrication processes. As used herein, “plasma characteristics” generally refers to location information and/or intensity information associated with plasma in a station. In some embodiments, the plasma characteristics may include a plasma centroid location within a region of the station or process chamber, plasma intensity as a function of position within a region of the station or process chamber, and/or a plasma non-uniformity metric within the station or process chamber. As used herein, “plasma uniformity” or “plasma non-uniformity” may refer to variations in plasma intensity across spatial regions of a station. In some embodiments, the plasma characteristics may be utilized in run-time control in which one or more changes are made to the fabrication tool during processing of a wafer undergoing a plasma-based operation. In some embodiments, the plasma characteristics may be utilized in run-by-run control in which changes are made to the fabrication tool after the plasma-based operation has been completed on a particular wafer. Examples of changes that may be made to the fabrication tool include changes to a plasma source, changes to process gases (e.g., a change to a process gas flow rate, a change to a process gas composition, or the like), temperature changes, pressure changes, process gap space, and/or any other suitable changes. In some embodiments, the plasma characteristics may be utilized for supervisory control, in which one or more changes to a subsequent fabrication operation to be performed on a wafer to which the plasma characteristics apply are to be made. By way of example, in an instance in which the plasma characteristics are associated with a plasma-based deposition operation performed on the wafer, the plasma characteristics may be utilized to determine changes to a subsequent etching operation the wafer is to undergo, such as changes in an etch rate, changes in an etchant species, plasma parameters, pedestal temperature profile, or the like.

It should be noted that, because plasma characteristics are correlated with wafer characteristics (e.g., wafer thickness, or the like), the plasma characteristics determined using the computer vision techniques described herein may be considered “virtual metrology.” In other words, rather than performing in situ or ex situ metrology in which various metrology tools are utilized to perform a physical inspection of a wafer to determine wafer characteristics such as thickness at various wafer locations, the techniques described herein may allow wafer characteristics to be estimated using computer vision techniques and algorithmic analysis techniques.

The techniques described herein may lead to improved wafer quality and/or a higher wafer yield, by allowing run-time control to be performed on a wafer undergoing processing. Such wafers may therefore be more likely to meet specifications. Moreover, the techniques described herein may result in cost savings by reducing the number of blanket wafers used for calibration and/or to configure tool settings. In some cases, the techniques described herein may be used in system calibration. For example, analysis of plasma characteristics may allow a determination that one or more components of a station or of a process chamber are misaligned. As a more particular example, responsive to identifying a particular pattern of plasma non-uniformity, a determination that a showerhead of a station is misaligned may be made. By way of example, a showerhead and a pedestal may initially be aligned (e.g., to be parallel to each other) when the components are at room temperature. Continuing with this example, the showerhead and the pedestal may become misaligned as the chamber is heated due to thermal expansion. Continuing still further with this example, the misalignment may be detected using camera data while the chamber is hot, and, in some cases, components may be re-aligned using camera data while the chamber is hot, allowing for more accurate component alignment. Re-alignment may be manually performed or may be performed using a robotic system (e.g., that may perform various calibration and adjustment processes). As another example, after repeated thermal cycling, a showerhead may droop. The techniques described herein may detect droop in the showerhead based on the plasma characteristics, which may allow for early maintenance action to be taken to replace the showerhead.

As another example, plasma characteristics may be used to identify faults in various sensors of a station or process chamber. As a more particular example, in an instance in which a sensor is faulty, and in which plasma characteristics indicate that other characteristics of a tool are anomalous (e.g., too low, too high, etc.), the sensor may be detected as being faulty based on the plasma characteristics. In some cases, an error condition of a sensor may be detected based on a discrepancy between plasma characteristics determined based on the obtained camera data and whether the sensor data is deemed anomalous. For example, in instances in which the camera data indicates anomalous plasma characteristics and in which the sensor data is non-anomalous, a sensor that provided the sensor data may be identified as faulty.

In some embodiments, camera data may be used to identify spatial anomalies that may not be easily identified or resolved using other sensors. For example, a sensor that provides data across a relatively large spatial region may provide data that effectively averages out an anomaly within the relatively large spatial region. In one example, the signal associated with the anomaly may be obscured by noise. In another example, in an instance in which the sensor data indicates two anomalies within the relatively large spatial region, the sensor data may average the signals associated with the two anomalies, thereby obscuring the relative locations and magnitudes of the two anomalies. Camera data, by virtue of combining both temporal data and higher resolution spatial data, may be useful for resolving and/or identifying such anomalies.

It should be noted that, in some embodiments, different stations of a multi-station fabrication tool may be matched or aligned, for example, to generate similar plasma characteristics across the multiple stations using camera data obtained in association with the multiple stations.

It should be noted that the techniques described herein may be utilized with any suitable type of plasma, such as a capacitively-coupled plasma (CCP), an inductively coupled plasma (ICP), a transformer coupled plasma (TCP), a microwave source plasma, a surface wave plasma, or any other suitable type of plasma.

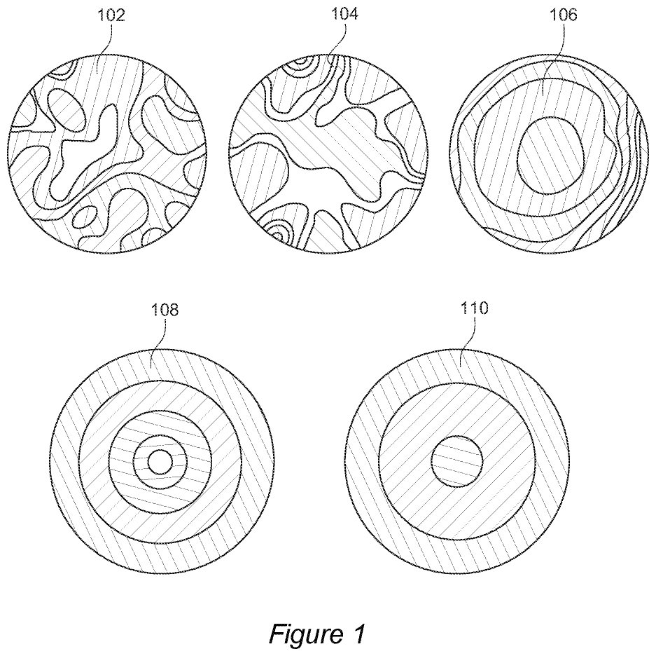

As described above, plasma uniformity within a process chamber or within a station of a process chamber may affect wafer characteristics. In some cases, depending on the chemical reactions occurring, plasma intensity may be inversely correlated with wafer thickness, where, for example, higher plasma intensities lead to decreased wafer thickness for a deposited layer. By way of example, FIG. 1 shows example wafer maps of different wafers having different wafer properties. Wafers 102, 104, and 106 are examples of wafers having relatively poor uniformity. For wafers 102, 104, and 106, wafer thickness (e.g., thickness of a deposited layer) varies across the wafer. By contrast, wafers 108 and 110 exhibit relatively good uniformity. It should be noted that, in some cases, plasma intensity may be directly correlated with wafer thickness, where higher plasma intensities lead to increased wafer thickness.

Plasma generated in association with a fabrication tool may be imaged. For example, camera data that includes plasma images may be analyzed to determine plasma characteristics, such as a location of plasma (e.g., indicated by a centroid of the plasma) with respect to various elements of the fabrication tool, a uniformity of the plasma across a portion of the fabrication tool, or the like. In some embodiments, the plasma characteristics may be utilized to predict wafer characteristics of a wafer undergoing fabrication in the fabrication tool, such as thickness of deposited layers on the wafer and/or uniformity of thickness across the wafer. In some embodiments, the plasma characteristics may be utilized to allow monitoring of the tool, monitoring of a process being performed in the tool, process control, diagnosis of a condition of a component in the tool, tool maintenance, or other function. For example, in some embodiments, the plasma characteristics may be utilized to perform run-time control of the tool (e.g., during performance of an operation), run-by-run control of the tool, and/or supervisory control (e.g., where plasma characteristics during performance of a first process on a wafer are utilized to modify steps or conditions of a second process to be subsequently performed on the wafer).

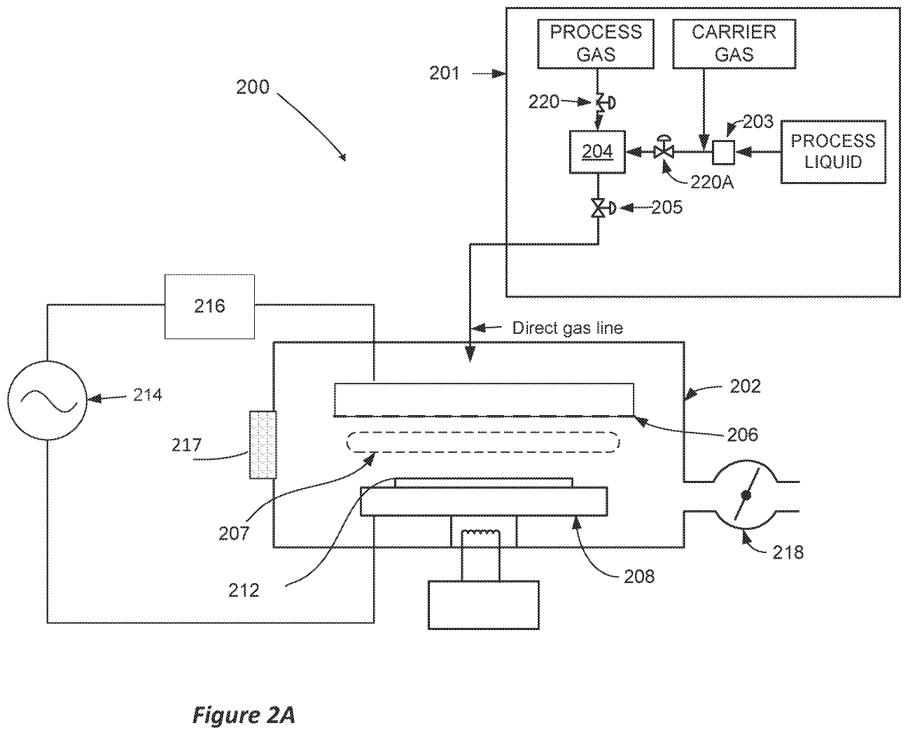

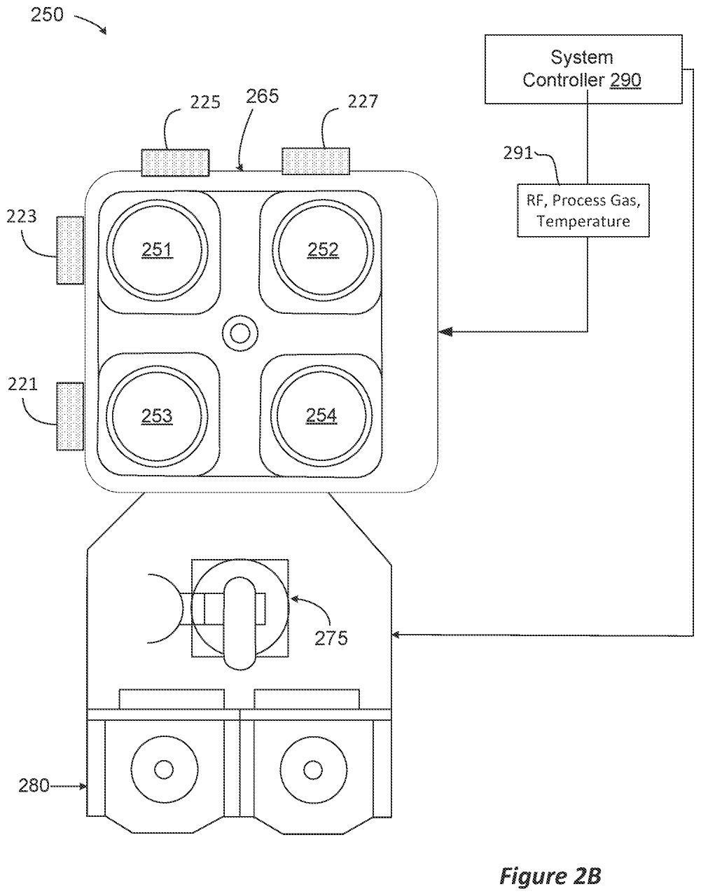

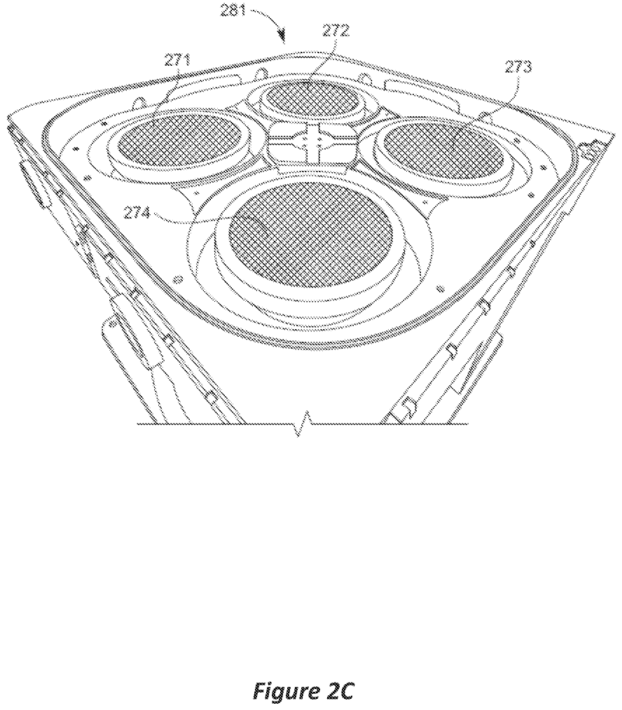

By strategically positioning one or more camera sensors on or near a fabrication tool, the sensors and associated analysis logic may capture plasma images of plasma within a portion of the fabrication tool. Those images may indicate plasma location within various regions of the tool, uniformity of plasma within and across regions of the tool, or the like. Using such plasma characteristics, analysis logic may facilitate monitoring, controlling, adjusting, servicing, and the like. As explained in some of the examples below, the location and orientation of a camera sensor determines the direction and path of a camera sensor's line of sight, and hence the components, features, and/or regions of the tool for which plasma images may be captured. The line of sight may be oriented substantially vertically, substantially horizontally, obliquely, or in some other direction with respect to the tool's frame of reference. Camera sensors may be positioned to capture images of the interior and/or exterior of a fabrication tool. Camera sensors may be positioned within a tool's chamber, on the exterior of a chamber, on an ancillary structure such as a wafer handling robot, a load lock, a dedicated wafer, or elsewhere. FIGS. 2A-2C present a few examples of process chambers and associated camera sensors.

FIG. 2A shows a fabrication tool denoted as substrate processing apparatus 200. Apparatus 200 may be configured for depositing films on or over a semiconductor substrate utilizing any number of processes. For example, apparatus 200 may be adapted for performing, in particular, PECVD, ALD, or ALE. Apparatus 200 includes a camera or camera sensor 217 on a chamber wall. Camera sensor 217 is configured to capture image data from the interior of apparatus 200.

Processing apparatus 200 of FIG. 2A may employ a single process station 202 of a process chamber with a single substrate holder 208 (e.g., a pedestal) in an interior volume, which may be maintained under vacuum by a vacuum pump 218. A showerhead 206 and a gas delivery system 201, which are fluidically coupled to the process chamber, may permit the delivery of film precursors, for example, as well as carrier and/or purge and/or process gases, secondary reactants, etc.

In FIG. 2A, gas delivery system 201 includes a mixing vessel 204 for blending and/or conditioning process gases for delivery to showerhead 206. One or more mixing vessel inlet valves 220 may control introduction of process gases to mixing vessel 204. Particular reactants may be stored in liquid form prior to vaporization and subsequent delivery to process station 202 of a process chamber. The implementation of FIG. 2A includes a vaporization point 203 for vaporizing liquid reactant to be supplied to mixing vessel 204. In some implementations, vaporization point 203 may include a heated liquid injection module. In some other implementations, vaporization point 203 may include a heated vaporizer. In yet other implementations, vaporization point 203 may be eliminated from the process station. In some implementations, a liquid flow controller upstream of vaporization point 203 may be provided for controlling a mass flow of liquid for vaporization and delivery to process station 202.

Showerhead 206 may operate to distribute process gases and/or reactants (e.g., film precursors) toward substrate 212 at the process station, the flow of which may be controlled by one or more valves upstream from the showerhead (e.g., valves 220, 220A, 205). In the implementation depicted in FIG. 2A, substrate 212 is depicted as located beneath showerhead 206, and is shown resting on a pedestal 208. Showerhead 206 may include any suitable shape and may include any suitable number and arrangement of ports for distributing process gases to substrate 212. In some implementations involving two or more stations, gas delivery system 201 includes valves or other flow control structures upstream from the showerhead, which can independently control the flow of process gases and/or reactants to each station so as to permit gas flow to one station while prohibiting gas flow to a second station. Furthermore, gas delivery system 201 may be configured to independently control process gases and/or reactants delivered to each station in a multi-station apparatus such that the gas composition provided to different stations is different; e.g., the partial pressure of a gas component may vary between stations at the same time.

In the implementation of FIG. 2A, gas volume 207 is depicted as being located beneath showerhead 206. In some implementations, pedestal 208 may be raised or lowered to expose substrate 212 to gas volume 207 and/or to vary the size of gas volume 207. The separation between pedestal 208 and showerhead 206 is sometimes referred to as a “gap.” Optionally, pedestal 208 may be lowered and/or raised during portions of the deposition process to modulate process pressure, reactant concentration, etc., within gas volume 207. Showerhead 206 and pedestal 208 are depicted as being electrically coupled to RF signal generator 214 and matching network 216 for coupling power to a plasma generator. Thus, showerhead 206 may function as an electrode for coupling radio frequency power into process station 202. RF signal generator 214 and matching network 216 may be operated at any suitable RF power level, which may operate to form plasma having a desired composition of radical species, ions, and electrons. In addition, RF signal generator 214 may provide RF power having more than one frequency component, such as a low-frequency component (e.g., less than about 2 MHz) as well as a high frequency component (e.g., greater than about 2 MHz). In some implementations, plasma ignition and maintenance conditions are controlled with appropriate hardware and/or appropriate machine-readable instructions in a system controller which may provide control instructions via a sequence of input/output control instructions.

For simplicity, processing apparatus 200 is depicted in FIG. 2A as a standalone station (202) of a process chamber for maintaining a low-pressure environment. However, some fabrication tools employ a plurality of process stations such as shown in FIG. 2B, which schematically depicts an implementation of a multi-station fabrication tool 205. Fabrication tool 250 employs a process chamber 265 that includes multiple fabrication process stations, each of which may be used to perform processing operations on a substrate held in a wafer holder, such as pedestal 208 of FIG. 2A, at a particular process station. In the implementation of FIG. 2B, the process chamber 265 is shown as having four process stations 251, 252, 253, and 254. However, in certain other implementations, multi-station processing apparatuses may have more or fewer process stations depending on the implementation and, for instance, the desired level of parallel wafer processing, size/space constraints, cost constraints, etc. FIG. 2B additionally shows substrate handler robot 275, which may operate under the control of system controller 290, configured to move substrates from a wafer cassette (not shown in FIG. 2B) from loading port 280 and into multi-station process chamber 265, and onto one of process stations 251, 252, 253, and 254.

As depicted, process station 253 has an associated camera or camera sensor 221 located and configured to obtain images from within process station 253 and, in some embodiments, from within process chamber 254. Process station 251 has two associated cameras or camera sensors 223 and 225. Camera sensor 223 is located and configured to obtain images from within process station 251 and, in some embodiments, from within process chamber 252. Camera sensor 225 is located and configured to obtain images from within process station 251 and, in some embodiments, from within process chamber 253. Process station 252 has an associated camera or camera sensor 227 located and configured to obtain images from within process station 252 and, in some embodiments, from within process chamber 254. Any one or more of camera sensors 221, 223, 225, and 227 may be optically coupled to the interior of process chamber 265 via view port, window, or other optical access aperture disposed in or on the chamber such as in the chamber wall. It should be understood that FIGS. 2A, 2B, and other system/apparatus figures herein merely present examples showing the number and location of camera sensors. Any number of camera sensors may be employed for a fabrication tool, and these sensors may be located at any of various positions in or around the tool and its chamber wall. For example, one or more cameras may be used at any given station. Further, a given camera sensor may be positioned and oriented to “look” at other stations other than the one it is most directly associated with (within line of sight). A chamber wall may include a substantially vertically aligned peripheral portion and/or a top portion and/or a bottom portion. A window or optical aperture may be placed in any one or more such portions. A camera sensor associated with any window or aperture may have a substantially vertical line of sight (e.g., it is substantially parallel to a vertical portion of a chamber wall), a substantially horizontal line of sight (e.g., it is substantially parallel to top and/or bottom portion of a chamber wall), or an oblique line of sight.

It should be noted that, as used herein, a camera sensor may capture light in various wavelength ranges, such as in the ultraviolet range, in the visible range, in the infrared range, or the like. In some implementations, a camera sensor may be associated with various spectral filters that are tuned for various wavelengths of interest. In some implementations, image data captured by a camera sensor may be digitally filtered to obtain data relevant to particular wavelengths. In some implementations, different channels may be collected separately by a camera sensor. For example, in some embodiments, a camera sensor may collect data for red, green, and blue channels separately such that the individual channels may be separately processed.

Fabrication tool 250 includes a system controller 290 configured to control process conditions and hardware states of process tool 250. It may interact with one or more sensors, gas flow subsystems, temperature subsystems, and/or plasma subsystems—collectively represented as block 291—to control process gas flow, thermal conditions, and plasma conditions as appropriate for controlling a fabrication process. System controller 290 and subsystems 291 may act to implement a recipe or other process conditions in the stations of process chamber 265.

In multi-station fabrication tools, an RF signal generator may be coupled to an RF signal distribution unit, which is configured to divide the power of the input signal into, for example, four output signals. Output signals from an RF signal distribution unit may possess similar levels of RF voltage and RF current, which may be conveyed to individual stations of a multi-station fabrication tool.

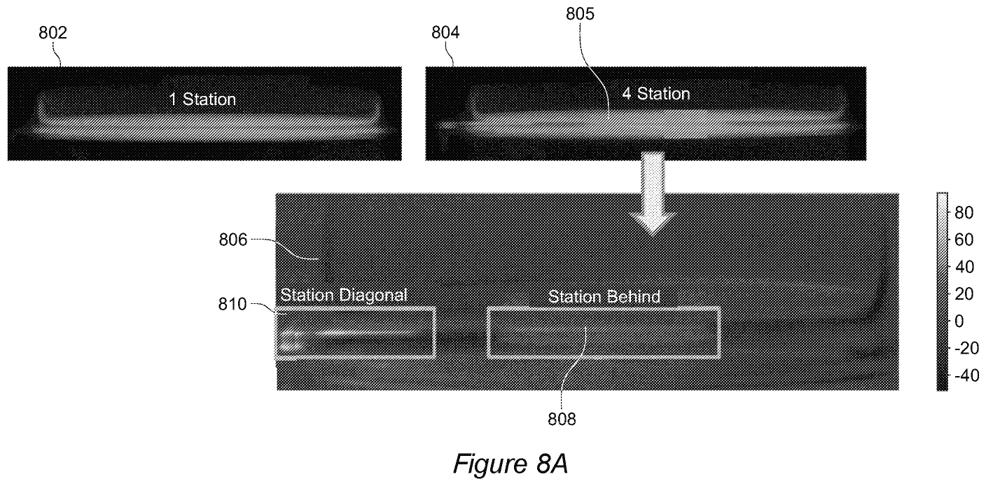

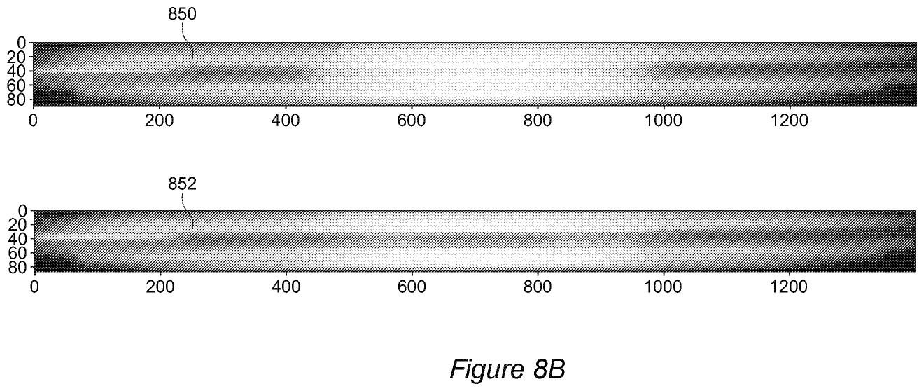

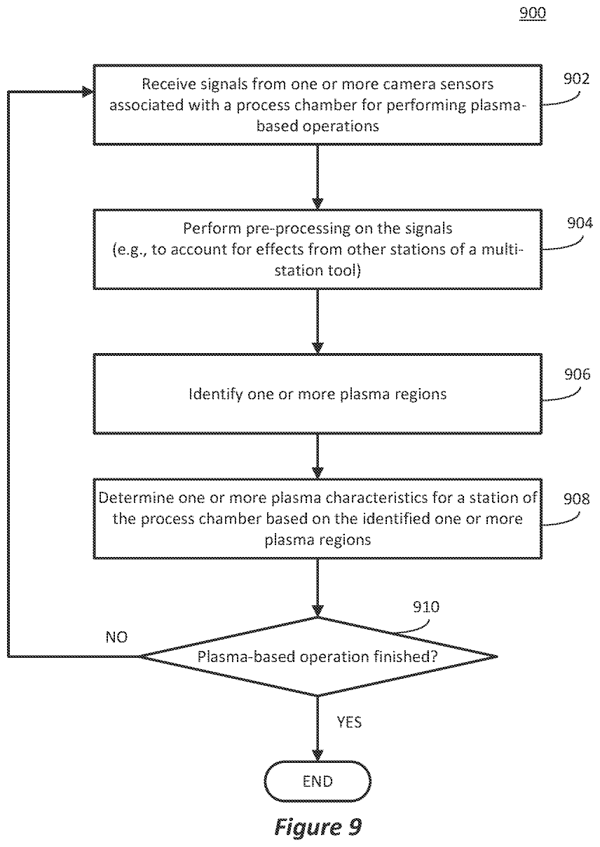

In some implementations, images captured from a particular camera sensor that is oriented predominantly to capture images from a first station of a multi-station apparatus may additionally capture images associated with other stations of the multi-station apparatus. FIG. 2C is an illustration of a portion of a multi-station apparatus which includes stations 271, 272, 273, and 274. A camera sensor (not shown) may be disposed in connection with a view port that is predominantly oriented to capture images of plasma within station 271. For example, such a camera sensor may have a field of view 281. However, as illustrated in FIG. 2C, field of view 281 may additionally overlap with other stations of the multi-station tool. For example, field of view 281 may additionally overlap with a station behind the station of interest (e.g., station 272, which is behind station 271). As another example, field of view 281 may overlap with a station diagonal to the station of interest (e.g., station 273, which is diagonal to station 271). When the field of view intersects multiple stations, images of plasma in the other stations may be captured by a camera sensor. The plasma from the other stations may be accounted for, for example, using the techniques shown in and described below in connection with FIGS. 8 and 9.

In some implementations, a camera sensor (or multiple sensors) may be associated with a process chamber or a station of a process chamber. A client device (e.g., a laptop computer, a desktop computer, a tablet computer, or the like) may trigger capture of one or more frames of image data by the camera sensor(s). In some cases, capture of the one or more frames of image data may be triggered based on a recipe sequence that indicates, e.g., time points and/or durations of plasma pulses or the like. In such cases, implementation of steps of the recipe sequence may be controlled by a tool computer or other tool controller, which may trigger capture of the frames of image data. For example, in some implementations, capture of a sequence of frames (e.g., 3 frames, 10 frames, 100 frames, or the like) may be triggered by the client device. In some implementations, in instances in which multiple camera sensors are utilized, the client device may trigger capture of one or more frames by each of the multiple camera sensors such that capture of the frames is synchronized across the multiple camera sensors. In some implementations, capturing one or more frames of image data may be synchronized to plasma pulses. For example, in some implementations, a frame of image data may be captured at a start of the plasma pulse. As another example, in instances in which multiple frames of image data are captured, the multiple frames may be synchronized with a plasma pulse such that a first frame substantially corresponds with a beginning of the plasma pulse and a last frame substantially corresponds with an end of the plasma pulse. By way of example, in an instance in which a plasma pulse is 100 milliseconds long, a sequence of 3 frames (e.g., corresponding to frame rate of 30 frames per second) may captured such that the first frame corresponds with the start of plasma pulse, the second frame corresponds to the middle of the plasma pulse (e.g., when plasma intensity is expected to be highest), and the third frame corresponds with the end of the plasma pulse.

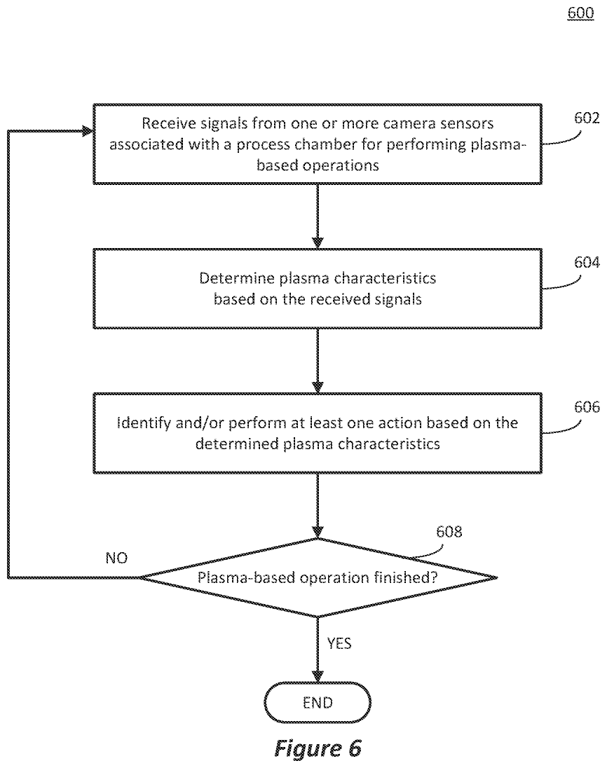

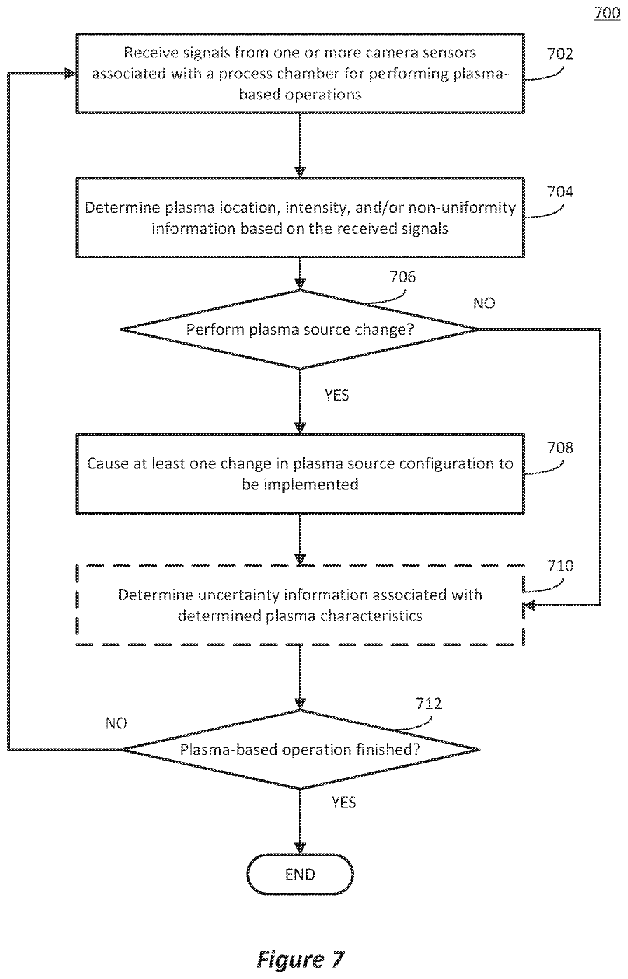

In some implementations, the camera data may be provided to an edge computing device and/or an edge analytics device that processes the camera data. For example, the edge computing device and/or the edge analytics device may determine one or more plasma characteristics indicated in one or more frames of camera data, such as location information associated with the plasma, non-uniformity information associated with the plasma, plasma intensity information, or the like. In some implementations, the edge computing device and/or the edge analytics device may utilize one or more computer vision algorithms and/or one or more machine learning models to determine the plasma characteristics, as shown in and described below in connection with FIGS. 8 and 9. In some implementations, the edge computing device and/or the edge analytics device may additionally determine control information for the process chamber of station of the process chamber. For example, in some implementations, the edge computing device and/or the edge analytics device may identify changes to process conditions to be implemented, changes to plasma sources to be implemented, or the like. Such control information may be used to affect the wafer characteristics in real-time, as shown in and described below in connection with FIGS. 6 and 7.

It should be noted that, in some implementations, multiple edge computing devices and/or edge analytics devices may be utilized. For example, in some implementations, data from each camera sensor device may be provided to a separate edge computing device and/or separate edge analytics device. As another example, in some implementations, a single edge computing device and/or edge analytics device may analyze data from multiple camera sensors.

In some implementations, the camera data and/or any analyses generated by the edge computing device and/or an edge analytics device may be stored in a database. Information stored in the database may be used, for example, to perform maintenance on the process chamber or station of the process chamber (e.g., based on plasma characteristics indicated in data stored in the database), to perform supervisory control for a particular wafer that has undergone processing in the process chamber or station of the process chamber, or the like. In some implementations, the database may be remote from the edge computing device and/or the edge analytics device. For example, in some implementations, the database may be stored in the “cloud.” In some embodiments, the information stored may include data other than camera data. For example, the data may include sensor data, such as pressure data, temperature data, power data, etc. Such sensor data may be stored in connection with information indicating plasma characteristics (e.g., determined from camera data). In some implementations, data may be stored in connection with recipe step information, such as sequence timing information, process gas information, etc.

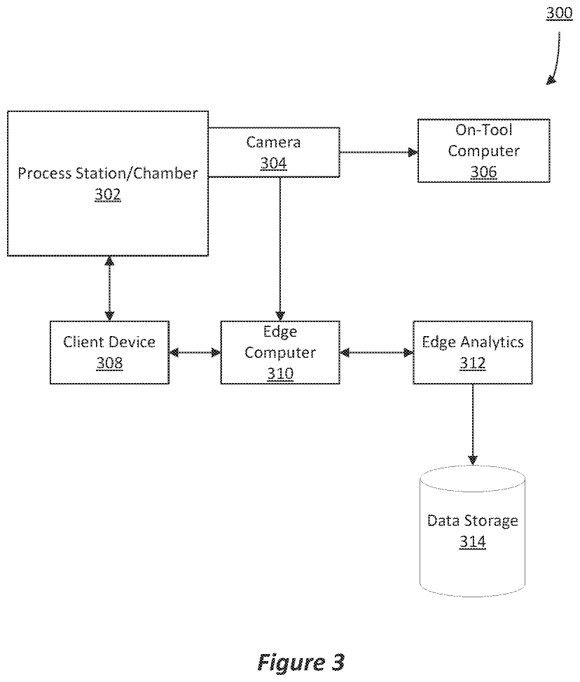

FIG. 3 shows an example of system 300 for evaluating plasma uniformity in accordance with some embodiments. As illustrated, system 300 includes a process station/chamber 302 and a camera 304. A client device 308 may trigger capture of one or more frames of image data by camera 304. Frames of image data captured by camera 304 may be transmitted to an edge computer 310. Edge computer 310 may store the image data in memory. In some implementations, edge analytics 312 may analyzed the captured image data, for example, to determine one or more plasma characteristics based on the image data. In some implementations, edge analytics 312 may additionally identify one or more changes to be made to process station/chamber 302. In some implementations, the camera data and/or analyses results may be stored in a data storage 314. In some implementations, data storage 314 may be associated with a server device that is remote from edge computer 310 and/or edge analytics 312. Additionally, in some implementations on-tool computer 306 may display real-time camera data, for example, for viewing by a process engineer during operation of process station/chamber 302. In some embodiments, a data feed associated with on-tool computer 306 may be viewed remotely, e.g., from outside the fabrication facility housing process station/chamber 302 via a remote connection. This may allow engineers or other users to interface with process station/chamber 302 remotely.

In some implementations, images of plasma obtained from one or more camera sensors may be processed and/or analyzed to determine plasma characteristics. For example, images may be analyzed by determining a heatmap that indicates an intensity of plasma at various locations or positions within a process chamber or within a station of a process chamber. As a more particular example, in some embodiments, such a heatmap may be used to identify one or more regions of a process chamber or station of a process chamber. In one example, the one or more regions may correspond to a region proximate a showerhead of the station or process chamber, a region proximate a pedestal of the station or process chamber, or the like. In one example, two regions may be identified, such as a first region proximate to a showerhead, and a second region proximate to a pedestal. In some embodiments, plasma characteristics (e.g., intensity, plasma centroid, plasma uniformity, or the like) may be determined for each region separately. In some embodiments, a region may be identified based on a determined heatmap using various image processing techniques and/or machine learning techniques, as described below in connection with FIG. 9.

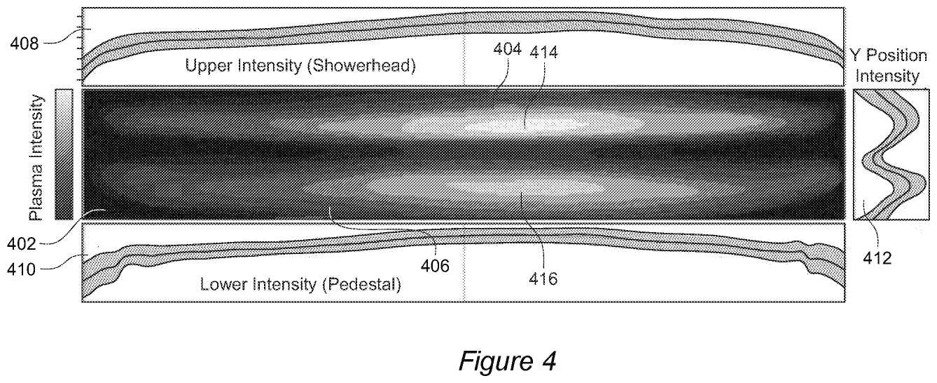

FIG. 4 shows an example heatmap and associated plasma characteristics corresponding to a station in accordance with some embodiments. As illustrated, a heatmap 402 includes two regions, a first region 404 corresponding to a showerhead of the station, and a second region 406 corresponding to a pedestal of the station. The heatmap associated with first region 404 may be used to construct a showerhead plasma intensity plot 408, which indicates plasma intensity as a function of lateral (e.g., along an x axes) position. Similarly, the heatmap associated with second region 406 may be used to construct a pedestal plasma intensity plot 410, which indicates plasma intensity as a function of lateral (e.g., along an x axes) position. Heatmap 402 may additionally be used to determine vertical plasma intensity 412, which may include, for example, at least a portion of a volume between the showerhead and the pedestal (sometimes referring to herein as a “gap.”). In some implementations, the heatmap associated with first region 404 and/or showerhead plasma intensity plot 408 may be used to determine a showerhead plasma centroid location 414. Similarly, in some implementations, the heatmap associated with second region 406 and/or pedestal plasma intensity plot 410 may be used to determine a pedestal plasma centroid location 416.

In some implementations, plasma characteristics may include a plasma intensity as a function of position (e.g., x position and/or y position), plasma centroid, and/or plasma uniformity. In some implementations, a plasma centroid location and/or a plasma uniformity metric may be determined based on plasma intensity values as a function of position. For example, in some embodiments, a plasma centroid location may be determined by determining a center of mass or center of gravity using the plasma intensity values indicated in the heatmap. As another example, a plasma non-uniformity metric may be determined based on a variance of plasma intensity as a function of position, a slope of plasma intensity as a function of position, or the like. It should be noted that, in some implementations, plasma characteristics may be determined for different regions of a station or process chamber separately. For example, plasma intensity may be determined separately for a region proximate to a showerhead and for a region proximate to a pedestal.

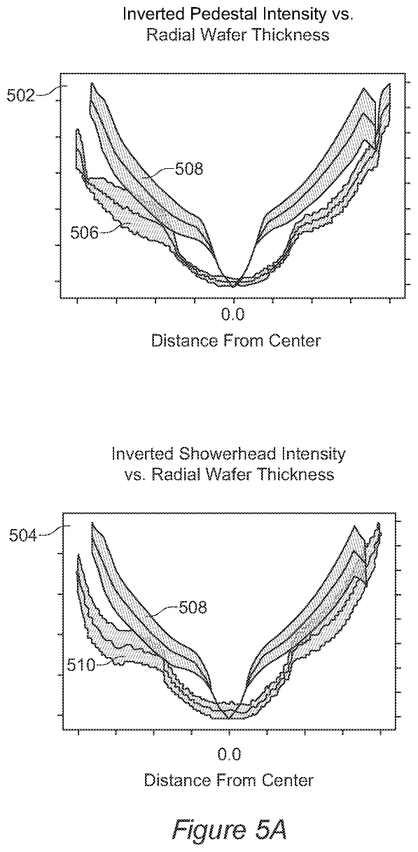

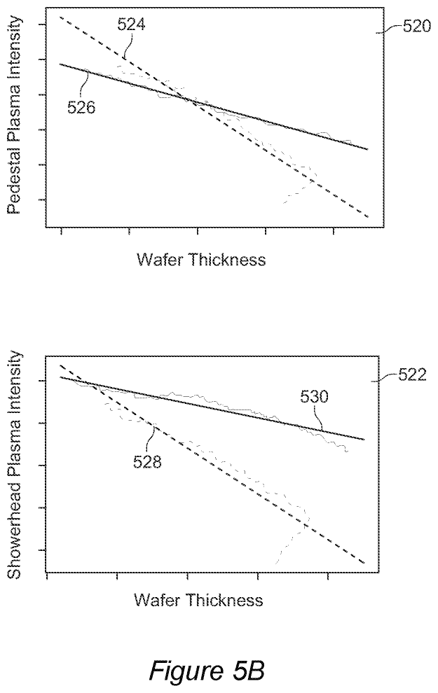

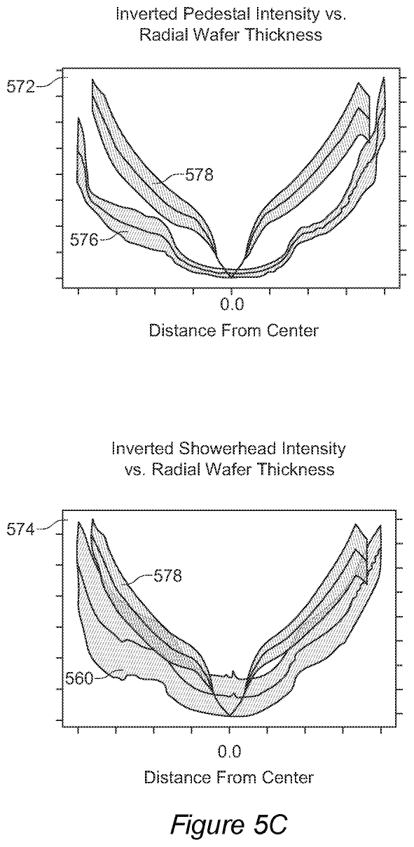

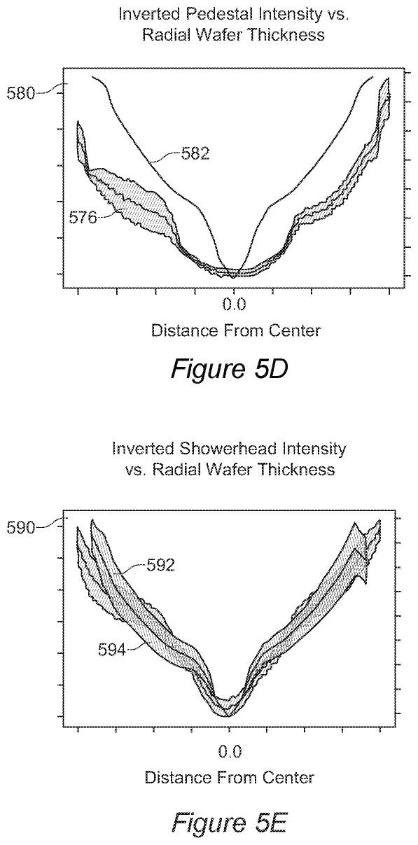

As described above, plasma intensity may be correlated with wafer thickness (e.g., a thickness of the wafer during a deposition process). FIG. 5A shows example plots of a relationship between pedestal plasma intensity and wafer thickness (plot 502) and a relationship between showerhead plasma intensity and wafer thickness (plot 504). It should be noted that the example plots shown in FIG. 5A correspond to a single frame of camera data for a single wafer. Referring to plot 502, pedestal plasma intensity is shown by curve 506, which represents an inverted plasma intensity. For example, because the plasma intensity is inverted, curve 506 has a minimum that substantially corresponds with the center position (marked as “0.0” in FIG. 5A), corresponding to a maximal plasma intensity. The wafer thickness is indicated by curve 508, which indicates the thickness of the wafer as a function of distance from the center position. As illustrated, minimum wafer thickness generally corresponds to maximal pedestal plasma intensity. Similarly, referring to plot 506, showerhead plasma intensity is shown by curve 510, which represents an inverted plasma intensity. For example, curve 510 has a minimum that substantially corresponds with the center position (marked as “0.0” in FIG. 5A), corresponding to a maximal showerhead plasma intensity. As illustrated, minimum wafer thickness (as indicated by curve 508) generally corresponds to maximal showerhead plasma intensity.

Referring to the plots shown in FIG. 5A, it should be noted that, in some cases, regions in which plasma intensity is not tightly correlated with wafer thickness may be due to an effect of captured plasma images from stations other than the station of interest, as described above in connection with FIG. 2C. Techniques for accounting for stations of a multi-station tool other than the station of interest are shown in and described below in connection with FIGS. 8 and 9.

Plasma intensity may correlate with wafer thickness across a population of wafers and over many frames of captured image data. FIG. 5B illustrates a relationship between pedestal plasma intensity and wafer thickness (plot 520) and showerhead plasma intensity and wafer thickness (plot 522) across multiple wafers and multiple frames of image data. Referring to plot 520, line 524 shows a best-fit line that relates plasma intensity for a right side of pedestal plasma heatmaps (e.g., right of center) as a function of wafer thickness, and line 526 shows a best-fit line that relates plasma intensity for a left side of the pedestal plasma heatmaps (e.g., left of center) as function of wafer thickness. Referring to plot 522, line 528 shows a best-fit line that relates plasma intensity for a right side of showerhead plasma heatmaps (e.g., right of center) as a function of wafer thickness, and line 530 shows a best-fit line that relates plasma intensity for a left side of the showerhead plasma heatmaps (e.g., left of center) as a function of wafer thickness. In some cases, a relationship between plasma intensity and wafer thickness may have an r² value of greater than about 0.85, greater than about 0.95, or the like.

In some embodiments, multiple frames of camera data may be blended or combined. This may cause the uncertainty in plasma intensity estimation and/or in wafer thickness to be changed relative to a single frame analysis. Recall that FIG. 5A illustrated plots of a relationship between pedestal plasma intensity and wafer thickness and showerhead plasma intensity and wafer thickness for a single frame. By contrast, FIG. 5C illustrates plots of the relationship between pedestal plasma intensity and wafer thickness (plot 572) and showerhead plasma intensity and wafer thickness (plot 574) where multiple frames of camera data are combined. Referring to plot 572, pedestal plasma intensity is shown by curve 576, and is an inverted curve, similar to that described above in connection with FIG. 5A. Curve 578 illustrates wafer thickness as a function of distance from the center. Curve 576 may be obtained by combining multiple frames of camera data. Note that the uncertainty (e.g., the shaded region) of the pedestal plasma intensity associated with curve 576 is less relative to the uncertainty associated with the single frame data as shown in plot 502. Turning to plot 574, curve 560 illustrates the inverted showerhead intensity obtained by averaging multiple frames of camera data. Note that the uncertainty (e.g., the shaded region) of the showerhead plasma intensity associated with curve 560 is greater than the uncertainty associated with the single frame data as shown in plot 504. In other words, combining or averaging multiple frames of camera data may increase or decrease the associated uncertainty associated with the determined plasma intensity. Whether the uncertainty increases or decreases may depend on how effectively light is captured by the one or more camera sensors. In some embodiments, combination of multiple frames of camera data may be achieved via averaging or the like.

In some implementations, an uncertainty associated with estimated wafer thickness may be reduced. Reduction in the uncertainty associated with estimated wafer thickness may in turn increase a correlation between plasma intensity and wafer thickness. Increase in the correlation between plasma intensity and corresponding wafer thickness may allow for more fine-grained control of plasma sources, plasma conditions, process conditions (e.g., pressure, temperature, gas composition, etc.) to achieve more uniform wafer thickness and wafer thickness that achieve a target specification. In some embodiments, wafer thickness uncertainty may be reduced using Fourier decomposition. For example, in some implementations, the radial component of wafer thickness may be isolated, thereby reducing the uncertainty associated with the radial wafer thickness. By way of example, FIG. 5D depicts plot 580, which corresponds to plot 572 of FIG. 5C with Fourier decomposition applied to reduce the uncertainty associated with wafer thickness. In particular, plot 580 illustrates the inverted pedestal intensity (curve 576) and the radial component of the wafer thickness (curve 582). Note that the uncertainty associated with the wafer thickness (e.g., uncertainty associated with curve 582) is substantially reduced relative to the uncertainty associated with curve 578 of plot 572 depicted in FIG. 5C. In other words, by isolating the radial component of the wafer thickness, the uncertainty as shown in FIG. 5D is reduced.

Note that Fourier decomposition may generate one or more other modes, or components, of wafer thickness other than a radial component. For example, the other modes may include an azimuthal mode, a noise component, or the like. In some implementations, while the radial component may be accessible using one camera collecting camera data for a given station, other components, such as an azimuthal component of wafer thickness, may be detectable using multiple camera capturing camera data for a given station. In instances in which multiple cameras are utilized, uncertainty associated with each mode may be reduced. Reducing uncertainty associated with multiple modes (e.g., a radial mode and an azimuthal mode) may allow for further improvements in correlation between wafer thickness and plasma intensity. In some implementations, in an instance in which multiple cameras are utilized thereby allowing for detectability of multiple modes or contributions (e.g., radial and azimuthal) of wafer thickness, hardware (e.g., hardware associated with a plasma source) or process conditions may be more accurately adjusted, e.g., to correct for system drifts, to achieve a target wafer thickness specification, etc. By way of example, in some implementations, use of multiple modes or contributions may allow a determination of one or more failure sources that cause wafer thickness non-uniformities and/or plasma non-uniformities. For example, the failure sources may be identified as one or more of a plasma anomaly, a poor or anomalous temperature distribution on the pedestal, a poor or anomalous gas flow, or the like. In some implementations, use of multiple modes (which may be derived from multiple cameras, as described above) may allow failure sources to be more quickly identified. Moreover, failure sources may be isolated within particular regions or areas of a station, thereby allowing failure source identification to be more granular with respect to spatial region within a station or chamber. In some embodiments, data derived from a Fourier decomposition may be provided to one or more machine learning models, which may be configured to identify one or more failure sources.

It should be understood that, in some implementations, a determined wafer thickness may be utilized to control processes or adjust hardware. For example, in some cases, showerhead and/or pedestal positioning may be adjusted based on wafer thickness determination while a chamber or station is in a hot state. Conventionally, a showerhead and/or pedestal tilt may be measured while the station is in a cold state based on wafer results. However, by utilizing wafer thickness predictions based on camera data, a robotic controller may be utilized to adjust showerhead and/or pedestal positioning (e.g., tilt) while the station is in a hot state. As another example, in some implementations, gas flow may be adjusted during a process based on wafer thickness predictions. As a more particular example, in a multi-station chamber, based on a wafer thickness prediction that a wafer of a first station has reached a desired thickness, gas flow may be diverted from the first station to one or more other stations in which the wafers have not yet reached the desired thickness. As yet another example, process settings and/or hardware may be adjusted in run-to-run control, as described below in connection with FIG. 6.

Described above in connection with FIG. 5D are techniques for reducing uncertainty related to wafer thickness. In some implementations, calibration techniques may be applied to align plasma intensity to wafer thickness, thereby effectively reducing an uncertainty associated with the plasma intensity. FIG. 5E illustrates the data depicted in FIG. 5A, which illustrates inverted pedestal plasma intensity and corresponding wafer thickness, with a calibration applied to adjust the pedestal plasma intensity. Curve 592 illustrates the wafer thickness, which corresponds to curve 508 of FIG. 5A. Curve 594 of FIG. 5E depicts the pedestal plasma intensity with a calibration applied. To generate the data shown in FIG. 5E, a calibration involving normalizing for the length of the showerhead and pedestal was applied. Additionally, a calibration was applied that corrected for the angles from which light was captured by the camera. Note that, relative to FIG. 5A, the pedestal plasma intensity (curve 594) and the wafer thickness (curve 592) are more closely aligned, indicating a better correlation between pedestal plasma intensity and wafer thickness. It should be understood that calibrations that involve normalizing based on pedestal and showerhead distance and/or angle of light incidence are only examples, and, in some implementations, other calibration techniques may be additionally or alternatively used to improve a correlation between the plasma intensity and predicted wafer thickness.

In some embodiments, plasma characteristics may be determined based on signals received from one or more camera sensors associated with a process chamber for performing plasma-based operations. For example, as described above, the plasma characteristics may include plasma location (e.g., a centroid of plasma within a particular region of a station or process chamber), plasma intensity as a function of location, plasma uniformity through a region of the station or process chamber, or the like. In some embodiments, one or more actions may be identified and/or performed based on the plasma characteristics. In some implementations, the one or more actions may be used for system control. In some embodiments, system control may include run-time control, in which controls of the apparatus may be modified based on the plasma characteristics during processing of a wafer. For example, aspects of the plasma source may be modified, process conditions (e.g., temperature, pressure, gas flow rate, gas composition, or the like) may be modified, and/or a recipe may be modified. In some embodiments, system control may include run-to-run control, in which controls of the apparatus may be modified based on the plasma characteristics between processing of successive wafers or successive batches of wafers. In some embodiments, system control may include supervisory control, in which aspects associated with a subsequent fabrication step the wafer undergoes are altered based on the plasma characteristics. For example, in an instance in which the plasma characteristics are associated with a deposition operation, aspects of a subsequent etch operation performed on the wafer may be altered, such as etch rate, etchant species, or the like.

FIG. 6 shows an example of a process 600 for determining and utilizing plasma characteristics associated with a plasma-based operation are shown in accordance with some embodiments. In some embodiments, blocks of process 600 may be performed by an edge computer or an edge analytics device operatively coupled to a station of a multi-station process chamber or a process chamber, as shown in and described above in connection with FIG. 3. In some embodiments, blocks of process 600 may be performed by a client device operatively coupled to the station of the multi-station process chamber or the process chamber, as shown in and described above in connection with FIG. 3. In some embodiments, two or more blocks of process 600 may be performed substantially in parallel. In some embodiments, one or more blocks of process 600 may be omitted. In some embodiments, blocks of process 600 may be performed in an order other than what is shown in FIG. 6.

Process 600 can begin at 602 by receiving signals from one or more camera sensors associated with a station or process chamber for performing plasma-based operations. In some embodiments, a camera sensor may be disposed with respect to a particular station of a multi-station tool such that the view of the camera sensor is primarily directed to the station. In some embodiments, such a camera sensor may have a view that additionally encompasses portions of other stations of a multi-station tool, as shown in and described above in connection with FIG. 2C. In some embodiments, the one or more camera sensors may capture image data at any suitable frame rate, such as 30 frames per second, 60 frames per second, or the like. In some embodiments, capture of image data may be synchronized with the plasma-based operation. For example, a sequence of frames may be synchronized such that a first frame substantially corresponds with a beginning of a plasma pulse, and a last frame substantially corresponds with an end of the plasma pulse. In some embodiments, the capture of the image data may be synchronized such that at least about 3 frames of image data, or at least about 5 frames of image data, are captured from a camera sensor during the course of a single plasma pulse. It should be noted that, in some implementations, signals associated with a sequence of frames may be integrated over time, for example, over a time window corresponding to a plasma pulse.

At 604, process 600 can determine plasma characteristics based on the received signals. For example, in some implementations, process 600 can identify one or more regions of interest within a frame (e.g., a first region corresponding to a showerhead of a station, a second region corresponding to a pedestal of the station, or the like). Continuing with this example, process 600 can identify plasma characteristics for each region, such as plasma intensity as a function of distance from the center of the region, plasma centroid for each region, plasma uniformity within the region, or the like. It should be noted that more detailed techniques for determining the plasma characteristics are shown in and described below in connection with FIGS. 8 and 9.

At 606, process 600 can identify and/or perform at least one action based on the determined plasma characteristics. In some embodiments, the at least one action can include logging or recording the plasma characteristics, e.g., in a database, as shown in and described above in connection with FIG. 3. In some embodiments, the at least one action be directed to run-time control, run-to-run-control, or supervisory control.

For example, in an instance in which the at least one action is directed to run-time control, process 600 can identify at least one change to be made to the station or the process chamber during performance of the current plasma-based operation and applicable to a wafer currently undergoing the current plasma-based operation. Examples of changes include: adjustments to a plasma source, adjustments to a temperature of the station or chamber, adjustments to a composition of process gases associated with the station or chamber, adjustments to flow rates of process gases, adjustments to a pressure of the station or process chamber, adjustments to components of the station or process chamber (e.g., changing a tilt or vertical position of a showerhead, changing a vertical position of a pedestal, etc.) or the like. For example, in an instance in which the plasma characteristics indicate that plasma intensity is not uniform across a region, process 600 can identify one or more plasma source adjustments to alter a plasma centroid location to compensate for the non-uniformity. For example, in an instance in which an ICP or TCP plasma is used, in which RF power is provided to one or more coils to generate the plasma, plasma source adjustments may include changing a showerhead tilt, changing which coil of a set of coils that are provided RF power, changing a current ratio between two coils of a set of coils (e.g., two concentric coils), or the like. As another example, in some embodiments, changes to a plasma source may include changing an RF power or RF frequency used to generate the plasma. As yet another example, in some embodiments, changes to a plasma source may include changing a duration of a plasma strike.

As another example, in an instance in which the at least one action is directed to run-by-run control, process 600 can identify at least one change to be made to the station or the process chamber after completion of the current plasma-based operation on the wafer undergoing processing. Examples of changes include: adjustments to a plasma source, adjustments to a temperature of the station or chamber, adjustments to a composition of process gases associated with the station or chamber, adjustments to flow rates of process gases, or the like. For example, in some embodiments, the adjustments may include adjustments (e.g., tilt, vertical position, or the like) to a showerhead, pedestal, or other component of the station or process chamber to account for drift in the apparatus over time. Similar adjustments may be made to the plasma source as described above in connection with run-time control.

As yet another example, in an instance in which the at least one action is directed to supervisory control, process 600 can identify at least one change to be made in a subsequent operation the current wafer will undergo after completion of the plasma-based operation. For example, in an instance in which the plasma-based operation is a deposition operation, process 600 can identify a change to be made in a subsequent etch operation the wafer will undergo. As a more particular example, responsive to determining, based on the plasma characteristics, that the plasma was relatively non-uniform in one or more regions, and therefore, that wafer thickness as a result of the deposition operation may be relatively non-uniform, process 600 can determine changes to the subsequent etch operation to account for and/or correct for the wafer thickness non-uniformity. As another more particular example, responsive to determining, based on the plasma characteristics, that the plasma had an intensity different than expected to generate a desired wafer thickness during the deposition operation, process 600 can determine changes to the subsequent etch operation to account for and/or correct for the difference in wafer thickness relative to that expected. Examples of etch operation changes may include a change in etch rate, a change in etchant species, plasma source changes (e.g., in instances of plasma-based etch operations), or the like.

It should be noted that in some implementations, process 600 may identify the at least one action without performing the at least one action. For example, in an instance of run-by-run control or supervisory control, process 600 may identify the at least one action and store the identified at least one action for later implementation. In some embodiments, in the instance of supervisory control, identified changes may be applied to a different station, e.g., a different station of a multi-station tool in which a subsequent operation is performed.

At 608, process 600 can determine whether the plasma-based operation has finished. If, at 608, process 600 determines that the plasma-based operation has not yet finished (“no” at 608), process 600 can loop back to block 602 and can receive additional signals from the one or more camera sensors. Process 600 may loop through blocks 602-608 during the course of the plasma-based operation.

Conversely, if, at 608, process 600 determines that the plasma-based operation has finished (“yes” at 608), process 600 can end.

FIG. 7 shows an example of a process 700 for implementing plasma source changes as part of run-by-run control in accordance with some embodiments. In some embodiments, blocks of process 700 may be performed by an edge computer or an edge analytics device operatively coupled to a station of a multi-station process chamber or a process chamber, as shown in and described above in connection with FIG. 3. In some embodiments, blocks of process 700 may be performed by a client device operatively coupled to the station of the multi-station process chamber or the process chamber, as shown in and described above in connection with FIG. 3. In some embodiments, two or more blocks of process 700 may be performed substantially in parallel. In some embodiments, one or more blocks of process 700 may be omitted. In some embodiments, blocks of process 700 may be performed in an order other than what is shown in FIG. 7.

At 702, process 700 can receive signals from one or more camera sensors associated with a process chamber for performing plasma-based operations. In some embodiments, a camera sensor may be disposed with respect to a particular station of a multi-station tool such that the view of the camera sensor is primarily directed to the station. In some embodiments, such a camera sensor may have a view that additionally encompasses portions of other stations of a multi-station tool, as shown in and described above in connection with FIG. 2C. In some embodiments, the one or more camera sensors may capture image data at any suitable frame rate, such as 30 frames per second, 60 frames per second, or the like. In some embodiments, capture of image data may be synchronized with the plasma-based operation. For example, a sequence of frames may be synchronized such that a first frame substantially corresponds with a beginning of a plasma pulse, and a last frame substantially corresponds with an end of the plasma pulse. In some embodiments, the capture of the image data may be synchronized such that at least about 3 frames of image data or at least about 5 frames of image data are captured from a camera sensor during the course of a single plasma pulse. It should be noted that, in some implementations, signals associated with a sequence of frames may be integrated over time, for example, over a time window corresponding to a plasma pulse.

At 704, process 700 may determine plasma location, plasma intensity, and/or plasma non-uniformity based on the received signals. For example, process 700 may construct a heatmap based on the received signals. In some embodiments, process 700 may identify one or more regions within the image corresponding to one or more regions of the station or process chamber, such as a showerhead region, a pedestal region, or the like. In some embodiments, process 700 may determine plasma location, plasma intensity, and/or plasma non-uniformity based on the constructed heatmap and for each of the one or more regions. For example, process 700 may determine a plasma centroid location by determining a center of mass or a center of gravity of the heatmap for each region. As another example, process 700 may determine plasma intensity as a function of distance from the center of a region based on the heatmap. As yet another example, process 700 may determine a plasma non-uniformity metric for a particular region based on a variance of the plasma intensity over the region.

At 706, process 700 can determine whether a plasma source change is to be performed. For example, process 700 may determine that a plasma source change is to be performed in response to determining that a plasma centroid location for a particular region differs from an expected or desired plasma centroid location by more than a predetermined threshold. As a more particular example, in an instance in which the expected or desired plasma centroid location is the center of a particular region (e.g., centered in the region proximate to the showerhead, centered in the region proximate to the pedestal, or the like), process 700 can determine that the plasma source change is to be performed responsive to determining that the plasma centroid location is laterally shifted from the center by more than a predetermined threshold amount. As another example, process 700 may determine that a plasma source change is to be performed in response to determining that a plasma non-uniformity metric for a particular region exceeds a predetermined threshold.

If, at 706, process 700 determines that a plasma source change is not to be performed (“no” at 706), process 700 can proceed to block 710. Conversely, if, at 706, process 700 determines that a plasma source change is to be performed (“yes” at 706), process 700 can proceed to block 708 and can cause at least one change in the plasma source configuration to be implemented. For example, in some embodiments, to modulate or change a plasma centroid location, changes may be made with respect to electrodes used to generate the plasma. As a more particular example, in an instances in which the plasma is an ICP or TCP plasma, the plasma centroid location may be changed by applying pulses to different coils in a sequence to correspondingly vary the plasma centroid location. As a specific example, a first sequence of pulses (e.g., 250 pulses, 300 pulses, or the like) may be applied to a coil at a first location, and a second sequence of pulses (e.g., 250 pulses, 300 pulses, or the like) may be applied to a coil at a second location to correspondingly shift the plasma centroid location. As another more particular example, the plasma centroid location and/or the plasma uniformity may be varied by changing a current ratio delivered to two or more coils. As another example, in some implementations, an RF power or RF frequency provided to an electrode to generate the plasma may be changed.

At 710, in some embodiments, process 700 may determine uncertainty information associated with the plasma characteristics (e.g., plasma centroid location, plasma intensity, plasma non-uniformity) determined at block 704. For example, process 700 may determine confidence levels associated with various determined plasma characteristics. In some implementations, uncertainty information may be determined using a single frame of camera data or using multiple frames of camera data combined (e.g., averaged). In instances in which multiple frames are combined, frames may be combined on a region-by-region basis.

In some embodiments, responsive to determining that the uncertainty information is outside a predetermined range, process 700 may loop back to block 708 and may cause an additional change in the plasma source configuration to be implemented. For example, process 700 may cause the plasma source configuration to be changed by an additional factor in the direction the plasma source configuration was initially changed during initial execution of block 708. By way of example, in an instance in which the current ratio is varied between two or more coils during an initial execution of block 708, responsive to the uncertainty information being outside a predetermined range, the current ratio may be further varied during a subsequent execution of block 708.

Note that, in some embodiments, process 700 may store the plasma characteristics, and, if determined, the uncertainty information. For example, process 700 may store the plasma characteristics and/or the uncertainty information in a log stored in a database, as shown in and described above in connection with FIG. 3. In some embodiments, logged information may be used at a later time to provide run-to-run control, to perform maintenance on the station or process chamber, or for any other suitable purpose.

At 712, process 700 can determine if the plasma-based operation has finished. If, at 712, process 700 determines that the plasma-based operation has not yet finished (“no” at 712), process 700 can loop back to block 700 and can receive additional signals from the one or more camera sensors. In some implementations, process 700 can loop through blocks 702-712 during performance of the plasma-based operation.

Conversely, if, at 712, process 700 determines that the plasma-based operation has finished (“yes” at 712), process 700 can end.

In some implementations, a camera sensor positioned at a viewport associated with a first station of a multi-station tool may capture image data relevant to other stations of the multi-station process tool. For example, the image data may include signals from a station behind the first station and/or a station diagonal to the first station. FIG. 8 shows an example of image data captured from a station behind a station of interest and a station diagonal to a station of interest. As illustrated, image 802 shows a frame of image data captured from a camera sensor positioned at a viewport associated with station 1, where the station of interest is station 1, and in which power is switched off to the remaining stations (e.g., stations 2-4) of the multi-station tool. In other words, image 802 shows the plasma contributions of station 1 by itself, with no contributions from plasma in other stations. Image 804 shows a frame of image data captured from the camera sensor positioned at a viewport associated with station 1 (and where the station of interest is station 1), and in which power is provided to station 4. As illustrated by the increased heatmap intensity in center portion 805 of image 804, plasma in station 4 contributes to the image data captured from a camera sensor positioned at a viewport associated with station 1. Referring to image 806, subtracting image 804 (which includes contributions from station 4) from image 802 (which includes contributions only from station 1, e.g., the station of interest), yields a contribution 808, which shows the contribution of station 4 to the image data captured by the camera sensor. It should be noted that a similar process may be performed for the station diagonal to station 1 to yield contribution 810, which shows the contribution of the diagonal station.

In some implementations, contributions from stations in a multi-station tool other than a station of interest associated with a particular camera sensor or set of camera sensors may be accounted for using various techniques. For example, in some implementations, a model may be constructed to characterize contributions of each station. In some implementations, a model of contributions from a particular station may be generated using images captured while power to the station is at different levels, or is switched off entirely. These images may be captured as part of a calibration technique. In some implementations, the model may then be utilized to subtract out contributions from stations other than a station of interest. As another example, in some implementations, certain portions of a frame of image data, each portion corresponding to a different station other than the station of interest, may be discarded prior to determining plasma characteristics for the station of interest. As a more particular example, in some implementations, a center portion of a frame of image data may be discarded to discount contributions from a station behind the station of interest. As another more particular example, in some implementations, one or more edge portions of the frame of image data may be discarded to discount contributions from a station diagonal to the station of interest. In some implementations, after discarding portions of the frame of image data, a model (e.g., a best fit model, or the like) may be utilized to construct modeled plasma intensity data for the discarded portions of the frame of image data. For example, a model that assumes plasma intensity decay (e.g., an exponential decay, a polynomial decay, a linear decay, or the like) from the center of a region of interest (e.g., a region proximate to the showerhead, a region proximate to the pedestal, or the like) may be used to fit data for the discarded portions of the frame of image data.

In some implementations, one or more computational transforms may be utilized to correct for the effects of plasma in stations other than the station of interest. For example, in some embodiments, a perspective transformation may be utilized to correct for effects of plasma in a station behind the station of interest. Such a perspective transformation may take advantage of the symmetry of a multi-station chamber by utilizing similarity between the stations of the multi-station chamber. By way of example, because a station that is positioned behind a station of interest may be similar to the station of interest, and because camera data that corresponds to the station behind the station of interest may represent objects or elements of interest at a smaller size than the corresponding objects or elements of interest from the station of interest due to depth, a perspective transform may be applied to the camera data. For example, an approximate perspective factor may be determined based on geometric information (e.g., dimensions associated with each station, sizes or dimensions of components within each station, etc.), and the current view associated with the camera data may be projected based on the perspective factor using a perspective transform. Continuing with this example, the projected view may then be subtracted from the original view associated with the obtained camera data to subtract out the effect of the station behind the station of interest.

FIG. 8B shows an example of accounting for a station behind a station of interest. As shown in FIG. 8B, panel 850 depicts an original view corresponding to camera data that includes plasma associated with both the station of interest and the station behind the station of interest. Panel 852 depicts a corrected view that subtracts out the effect of plasma in the station behind the station of interest. Panel 852 may be obtained using a perspective transform as described above.

FIG. 9 shows an example of a process 900 for processing signals received from one or more camera sensors in accordance with some embodiments. In some implementations, blocks of process 900 may be executed by an edge computer and/or an edge analytics device, as shown in and described above in connection with FIG. 3. In some implementations, blocks of process 900 may be executed in an order other than what is shown in FIG. 9. In some embodiments, two or more blocks of process 900 may be executed substantially in parallel. In some embodiments, one or more blocks of process 900 may be omitted.

Process 900 can begin at 902 by receiving signals from one or more camera sensors associated with a process chamber for performing plasma-based operations. The received signals may correspond to any suitable number of frames (e.g., 3 frames, 10 frames, 20 frames, or the like). In some embodiments, frames of image data may have been captured by the one or more camera sensors in a manner that is substantially synchronized with a plasma pulse applied in the process chamber or a station of the process chamber.

At 904, process 900 can perform pre-processing on the received signals. For example, in some implementations, the pre-processing can account for effects of other stations of a multi-station tool other than a station of interest. As a more particular example, as described above in connection with FIG. 8, heatmap signatures of plasma in a station behind and/or diagonal to a station of interest may be accounted for. In one example, portions of one or more frames of image data associated with the received signals may be discarded, such as portions of the one or more frames in which plasma signatures from other stations are visible (e.g., a center region corresponding to a center of a showerhead and/or a pedestal, an edge region corresponding to an edge of a showerhead and/or a pedestal, or the like, as shown in and described above in connection with FIG. 8). In some implementations, after discarding one or more portions of one or more frames of image data, image data corresponding to the discarded portions may be reconstructed using a model, such as a best fit model that represents plasma intensity as a function of distance from a center position within the station of interest (e.g., a center position corresponding to a center region proximate to the showerhead and/or the pedestal). In another example, a trained model may be used to modify the received signals to subtract out effects of plasma in stations other than the station of interest. Such a trained model may be a trained machine learning model (e.g., a machine learning model trained using supervised learning, a machine learning model trained using unsupervised learning, and/or any other suitable type of machine learning model.

In some implementations, the pre-processing may involve integrating the received signals as a function of time. For example, in an instance in which the received signals include two or more frames corresponding to samples of a plasma pulse, the received signals may be integrated across a duration of the plasma pulse.

At 906, process 900 can identify one or more plasma regions from the pre-processed signals. For example, process 900 can identify one or more regions within a particular frame of image data. Each region may correspond to a different region within the station or the process chamber. By way of example, one region may correspond to a region proximate to a showerhead. As another example, another region may correspond to a region proximate to a pedestal. Process 900 may identify any suitable number of plasma regions within a frame, such as 1, 2, 3, or the like.

In some implementations, process 900 may identify the one or more plasma regions using various image processing techniques. For example, in some implementations, process 900 may use edge detection on a heatmap associated with a frame of image data (e.g., using a Canny edge detector, a Sobel filter, neural networks for segmentation and/or edge detection, or any other suitable edge detection technique) to identify borders within the frame of image data. Continuing with this example, in some implementations, process 900 may use a classifier to classify regions within the identified borders as belonging to particular types of regions (e.g., a region proximate to a showerhead, a region proximate to a pedestal, or the like).

In some implementations, process 900 may identify the one or more plasma regions using one or more neural networks trained to perform semantic segmentation on a heatmap associated with a frame of image data. For example, such a neural network may take, as input, a heatmap associated with a frame of image data and generate, as an output, clusters of pixels, where each cluster of pixel is classified as being associated with a region of the station or the process chamber (e.g., a region proximate to a showerhead, a region proximate to a pedestal, a region proximate to a chamber wall, or the like). Continuing with this example, process 900 may then select clusters of pixels associated with plasma regions for further analysis in block 908. As a more particular example, process 900 may select a cluster of pixels associated with a region proximate to the showerhead, a cluster of pixels associated with a region proximate to the pedestal, or the like. Examples of neural networks that may be used include a convolutional neural network, a U-Net, or the like. In some instances, using a neural network to identify the one or more plasma regions may be faster and/or more efficient than using edge detection techniques, thereby allowing the captured image data to be processed in near real-time.

At 908, process 900 may determine one or more plasma characteristics for a station of the process chamber based on the identified one or more plasma regions. As described above, the plasma characteristics may include a plasma centroid location associated with each plasma region, a plasma intensity as a function of distance across each plasma region, and/or a plasma non-uniformity within each plasma region. In some embodiments, a plasma centroid location may be determined using a center of gravity of the heatmap within a plasma region. In some embodiments, plasma non-uniformity may be determined based on a variance of plasma intensity within each plasma region, a slope of the plasma intensity as a function of distance across the plasma region, or the like.

It should be noted that the plasma characteristics determined by process 900 may be utilized for run-time control, run-by-run control, and/or supervisory control, as described above in connection with FIGS. 6 and 7. In some implementations, the plasma characteristics may be stored, for example, in a database or in the “cloud,” as described above in connection with FIG. 3.

At 910, process 900 can determine if the plasma-based operation has finished. If, at 910, process 900 determines that the plasma-based operation has not yet finished (“no” at 910), process 900 can loop back to block 902 and receive additional signals from the one or more camera sensors. Conversely, if, at 910, process 900 determines that the plasma-based operation has finished (“yes” at 910), process 900 can end.

### Context for Disclosed Computational Embodiments

Certain embodiments disclosed herein relate to computational systems for determining plasma characteristics.

Many types of computing systems having any of various computer architectures may be employed as the disclosed systems for implementing algorithms as described herein. For example, the systems may include software components executing on one or more general purpose processors or specially designed processors such as Application Specific Integrated Circuits (ASICs) or programmable logic devices (e.g., Field Programmable Gate Arrays (FPGAs)). Further, the systems may be implemented on a single device or distributed across multiple devices. The functions of the computational elements may be merged into one another or further split into multiple sub-modules.

In some embodiments, code executed during generation or execution of a technique described herein on an appropriately programmed system can be embodied in the form of software elements which can be stored in a nonvolatile storage medium (such as optical disk, flash storage device, mobile hard disk, etc.), including a number of instructions for making a computer device (such as personal computers, servers, network equipment, etc.).

At one level a software element is implemented as a set of commands prepared by the programmer/developer. However, the module software that can be executed by the computer hardware is executable code committed to memory using “machine codes” selected from the specific machine language instruction set, or “native instructions,” designed into the hardware processor. The machine language instruction set, or native instruction set, is known to, and essentially built into, the hardware processor(s). This is the “language” by which the system and application software communicates with the hardware processors. Each native instruction is a discrete code that is recognized by the processing architecture and that can specify particular registers for arithmetic, addressing, or control functions; particular memory locations or offsets; and particular addressing modes used to interpret operands. More complex operations are built up by combining these simple native instructions, which are executed sequentially, or as otherwise directed by control flow instructions.

The inter-relationship between the executable software instructions and the hardware processor is structural. In other words, the instructions per se are a series of symbols or numeric values. They do not intrinsically convey any information. It is the processor, which by design was preconfigured to interpret the symbols/numeric values, which imparts meaning to the instructions.

The methods and techniques used herein may be configured to execute on a single machine at a single location, on multiple machines at a single location, or on multiple machines at multiple locations. When multiple machines are employed, the individual machines may be tailored for their particular tasks. For example, operations requiring large blocks of code and/or significant processing capacity may be implemented on large and/or stationary machines.

In addition, certain embodiments relate to tangible and/or non-transitory computer readable media or computer program products that include program instructions and/or data (including data structures) for performing various computer-implemented operations. Examples of computer-readable media include, but are not limited to, semiconductor memory devices, phase-change devices, magnetic media such as disk drives, magnetic tape, optical media such as CDs, magneto-optical media, and hardware devices that are specially configured to store and perform program instructions, such as read-only memory devices (ROM) and random access memory (RAM). The computer readable media may be directly controlled by an end user or the media may be indirectly controlled by the end user. Examples of directly controlled media include the media located at a user facility and/or media that are not shared with other entities. Examples of indirectly controlled media include media that is indirectly accessible to the user via an external network and/or via a service providing shared resources such as the “cloud.” Examples of program instructions include both machine code, such as produced by a compiler, and files containing higher level code that may be executed by the computer using an interpreter.

In various embodiments, the data or information employed in the disclosed methods and apparatus is provided in an electronic format. Such data or information may include various coefficients to be used in calculations, and the like. As used herein, data or other information provided in electronic format is available for storage on a machine and transmission between machines. Conventionally, data in electronic format is provided digitally and may be stored as bits and/or bytes in various data structures, lists, databases, etc. The data may be embodied electronically, optically, etc.

System software typically interfaces with computer hardware and associated memory. In some embodiments, the system software includes operating system software and/or firmware, as well as any middleware and drivers installed in the system. The system software provides basic non-task-specific functions of the computer. In contrast, the modules and other application software are used to accomplish specific tasks. Each native instruction for a module is stored in a memory device and is represented by a numeric value.

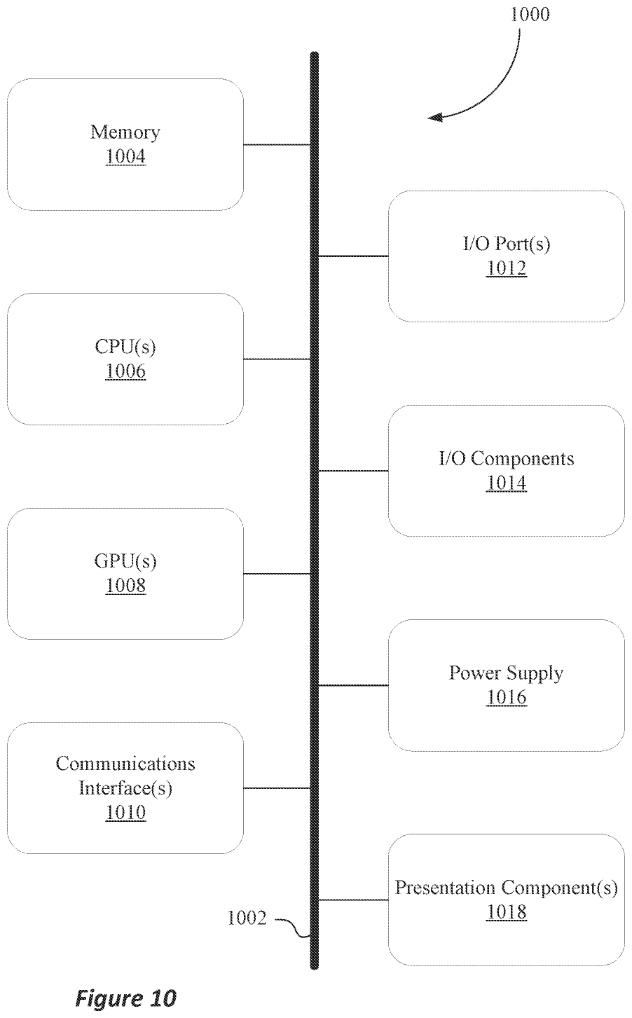

FIG. 10 is a block diagram of an example of the computing device 1000 suitable for use in implementing some embodiments of the present disclosure. For example, device 1000 may be suitable for implementing some or all functions of image analysis logic disclosed herein.

Computing device 1000 may include a bus 1002 that directly or indirectly couples the following devices: memory 1004, one or more central processing units (CPUs) 1006, one or more graphics processing units (GPUs) 1008, a communication interface 1010, input/output (I/O) ports 1012, input/output components 1014, a power supply 1016, and one or more presentation components 1018 (e.g., display(s)). In addition to CPU 1006 and GPU 1008, computing device 1000 may include additional logic devices that are not shown in FIG. 10, such as but not limited to an image signal processor (ISP), a digital signal processor (DSP), an ASIC, an FPGA, or the like.

Although the various blocks of FIG. 10 are shown as connected via the bus 1002 with lines, this is not intended to be limiting and is for clarity only. For example, in some embodiments, a presentation component 1018, such as a display device, may be considered an I/O component 1014 (e.g., if the display is a touch screen). As another example, CPUs 1006 and/or GPUs 1008 may include memory (e.g., the memory 1004 may be representative of a storage device in addition to the memory of the GPUs 1008, the CPUs 1006, and/or other components). In other words, the computing device of Figure ‘0 is merely illustrative. Distinction is not made between such categories as “workstation,” “server,” “laptop,” “desktop,” “tablet,” “client device,” “mobile device,” “hand-held device,” “electronic control unit (ECU),” “virtual reality system,” and/or other device or system types, as all are contemplated within the scope of the computing device of FIG. 10.

Bus 1002 may represent one or more busses, such as an address bus, a data bus, a control bus, or a combination thereof. The bus 1002 may include one or more bus types, such as an industry standard architecture (ISA) bus, an extended industry standard architecture (EISA) bus, a video electronics standards association (VESA) bus, a peripheral component interconnect (PCI) bus, a peripheral component interconnect express (PCIe) bus, and/or another type of bus.

Memory 1004 may include any of a variety of computer-readable media. The computer-readable media may be any available media that can be accessed by the computing device 1000. The computer-readable media may include both volatile and nonvolatile media, and removable and non-removable media. By way of example, and not limitation, the computer-readable media may comprise computer-storage media and/or communication media.

The computer-storage media may include both volatile and nonvolatile media and/or removable and non-removable media implemented in any method or technology for storage of information such as computer-readable instructions, data structures, program modules, and/or other data types. For example, memory 1004 may store computer-readable instructions (e.g., that represent a program(s) and/or a program element(s), such as an operating system. Computer-storage media may include, but is not limited to, RAM, ROM, EEPROM, flash memory or other memory technology, CD-ROM, digital versatile disks (DVD) or other optical disk storage, magnetic cassettes, magnetic tape, magnetic disk storage or other magnetic storage devices, or any other medium which can be used to store the desired information and which can be accessed by computing device 1000. As used herein, computer storage media does not comprise signals per se.

The communication media may embody computer-readable instructions, data structures, program modules, and/or other data types in a modulated data signal such as a carrier wave or other transport mechanism and includes any information delivery media. The term “modulated data signal” may refer to a signal that has one or more of its characteristics set or changed in such a manner as to encode information in the signal. By way of example, and not limitation, the communication media may include wired media such as a wired network or direct-wired connection, and wireless media such as acoustic, RF, infrared and other wireless media. Combinations of any of the above should also be included within the scope of computer-readable media.

CPU(s) 1006 may be configured to execute the computer-readable instructions to control one or more components of the computing device 1000 to perform one or more of the methods and/or processes described herein. CPU(s) 1006 may each include one or more cores (e.g., one, two, four, eight, twenty-eight, seventy-two, etc.) that are capable of handling a multitude of software threads simultaneously. CPU(s) 1006 may include any type of processor and may include different types of processors depending on the type of computing device 1000 implemented (e.g., processors with fewer cores for mobile devices and processors with more cores for servers). For example, depending on the type of computing device 1000, the processor may be an ARM processor implemented using Reduced Instruction Set Computing (RISC) or an x86 processor implemented using Complex Instruction Set Computing (CISC). Computing device 1000 may include one or more CPUs 1006 in addition to one or more microprocessors or supplementary co-processors, such as math co-processors.

GPU(s) 1008 may be used by computing device 1000 to render graphics (e.g., 3D graphics). GPU(s) 1008 may include many (e.g., tens, hundreds, or thousands) of cores that are capable of handling many software threads simultaneously. GPU(s) 1008 may generate pixel data for output images in response to rendering commands (e.g., rendering commands from CPU(s) 1006 received via a host interface). GPU(s) 1008 may include graphics memory, such as display memory, for storing pixel data. The display memory may be included as part of memory 1004. GPU(s) 1008 may include two or more GPUs operating in parallel (e.g., via a link). When combined, each GPU 1008 can generate pixel data for different portions of an output image or for different output images (e.g., a first GPU for a first image and a second GPU for a second image). Each GPU can include its own memory or can share memory with other GPUs.

In examples where the computing device 1000 does not include the GPU(s) 1008, the CPU(s) 1006 may be used to render graphics.

Communication interface 1010 may include one or more receivers, transmitters, and/or transceivers that enable computing device 1000 to communicate with other computing devices via an electronic communication network, included wired and/or wireless communications. Communication interface 1010 may include components and functionality to enable communication over any of a number of different networks, such as wireless networks (e.g., Wi-Fi, Z-Wave, Bluetooth, Bluetooth LE, ZigBee, etc.), wired networks (e.g., communicating over Ethernet), low-power wide-area networks (e.g., LoRaWAN, SigFox, etc.), and/or the internet.

I/O ports 1012 may enable the computing device 1000 to be logically coupled to other devices including I/O components 1014, presentation component(s) 1018, and/or other components, some of which may be built in to (e.g., integrated in) computing device 1000. Illustrative I/O components 1014 include a microphone, mouse, keyboard, joystick, track pad, satellite dish, scanner, printer, wireless device, etc. I/O components 1014 may provide a natural user interface (NUI) that processes air gestures, voice, or other physiological inputs generated by a user. In some instances, inputs may be transmitted to an appropriate network element for further processing. An NUI may implement any combination of speech recognition, stylus recognition, facial recognition, biometric recognition, gesture recognition both on screen and adjacent to the screen, air gestures, head and eye tracking, and touch recognition (as described in more detail below) associated with a display of computing device 1000. Computing device 1000 may be include depth cameras, such as stereoscopic camera systems, infrared camera systems, RGB camera systems, touchscreen technology, and combinations of these, for gesture detection and recognition. Additionally, computing device 1000 may include accelerometers or gyroscopes (e.g., as part of an inertia measurement unit (IMU)) that enable detection of motion. In some examples, the output of the accelerometers or gyroscopes may be used by computing device 1000 to render immersive augmented reality or virtual reality.

Power supply 1016 may include a hard-wired power supply, a battery power supply, or a combination thereof. Power supply 1016 may provide power to computing device 1000 to enable the components of computing device 1000 to operate.

Presentation component(s) 1018 may include a display (e.g., a monitor, a touch screen, a television screen, a heads-up-display (HUD), other display types, or a combination thereof), speakers, and/or other presentation components. Presentation component(s) 1018 may receive data from other components (e.g., GPU(s) 1008, CPU(s) 1006, etc.), and output the data (e.g., as an image, video, sound, etc.).

The disclosure may be described in the general context of computer code or machine-useable instructions, including computer-executable instructions such as program modules, being executed by a computer or other machine, such as a personal data assistant or other handheld device. Generally, program modules including routines, programs, objects, components, data structures, etc., refer to code that perform particular tasks or implement particular abstract data types. The disclosure may be practiced in a variety of system configurations, including hand-held devices, consumer electronics, general-purpose computers, more specialty computing devices, etc. The disclosure may also be practiced in distributed computing environments where tasks are performed by remote-processing devices that are linked through a communications network.

### CONCLUSION

In the description, numerous specific details were set forth in order to provide a thorough understanding of the presented embodiments. The disclosed embodiments may be practiced without some or all of these specific details. In other instances, well-known process operations were not described in detail to not unnecessarily obscure the disclosed embodiments. While the disclosed embodiments were described in conjunction with the specific embodiments, it will be understood that the specific embodiments are not intended to limit the disclosed embodiments.

Unless otherwise indicated, the method operations and device features disclosed herein involves techniques and apparatus commonly used in metrology, semiconductor device fabrication technology, software design and programming, and statistics, which are within the skill of the art.

Unless defined otherwise herein, all technical and scientific terms used herein have the same meaning as commonly understood by one of ordinary skill in the art. Various scientific dictionaries that include the terms included herein are well known and available to those in the art. Although any methods and materials similar or equivalent to those described herein find use in the practice or testing of the embodiments disclosed herein, some methods and materials are described.

Numeric ranges are inclusive of the numbers defining the range. It is intended that every maximum numerical limitation given throughout this specification includes every lower numerical limitation, as if such lower numerical limitations were expressly written herein. Every minimum numerical limitation given throughout this specification will include every higher numerical limitation, as if such higher numerical limitations were expressly written herein. Every numerical range given throughout this specification will include every narrower numerical range that falls within such broader numerical range, as if such narrower numerical ranges were all expressly written herein.

The headings provided herein are not intended to limit the disclosure.

As used herein, the singular terms “a,” “an,” and “the” include the plural reference unless the context clearly indicates otherwise. The term “or” as used herein, refers to a non-exclusive or, unless otherwise indicated.

Various computational elements including processors, memory, instructions, routines, models, or other components may be described or claimed as “configured to” perform a task or tasks. In such contexts, the phrase “configured to” is used to connote structure by indicating that the component includes structure (e.g., stored instructions, circuitry, etc.) that performs the task or tasks during operation. As such, the unit/circuit/component can be said to be configured to perform the task even when the specified component is not necessarily currently operational (e.g., is not on).

The components used with the “configured to” language may refer to hardware—for example, circuits, memory storing program instructions executable to implement the operation, etc. Additionally, “configured to” can refer to generic structure (e.g., generic circuitry) that is manipulated by software and/or firmware (e.g., an FPGA or a general-purpose processor executing software) to operate in manner that is capable of performing the recited task(s). Additionally, “configured to” can refer to one or more memories or memory elements storing computer executable instructions for performing the recited task(s). Such memory elements may include memory on a computer chip having processing logic. In some contexts, “configured to” may also include adapting a manufacturing process (e.g., a semiconductor fabrication facility) to fabricate devices (e.g., integrated circuits) that are adapted to implement or perform one or more tasks.

1. A method comprising:
obtaining signals from one or more camera sensors optically coupled to one or more optical access apertures of a device fabrication process chamber during performance of a plasma-based operation;
determining, from the signals, plasma characteristics during the performance of the plasma-based operation; and
determining, from the plasma characteristics, a non-uniformity of one or more wafer characteristics of a wafer undergoing the plasma-based operation.

2. The method of claim 1, further comprising using the determined non-uniformity to identify at least one change to be made to the plasma-based operation and/or the device fabrication process chamber.

3. The method of claim 1, wherein the plasma characteristics comprise a metric indicative of plasma uniformity within a portion of the device fabrication process chamber.

4. The method of claim 1, wherein the plasma characteristics comprise a metric indicative of plasma location within a portion of the device fabrication process chamber and a metric indicative of an intensity of plasma at different portions of the device fabrication process chamber.

5. The method of claim 1, further comprising:
determining a change that is to be made to one or more process conditions performed by the device fabrication process chamber.

6. The method of claim 5, wherein the process conditions comprise: adjustments to a plasma source associated with the device fabrication process chamber, adjustments to a temperature associated with the device fabrication process chamber, adjustments to a composition of process gases associated with the device fabrication process chamber, or adjustments to flow rates of the process gases.

7. The method of claim 1, further comprising:
determining, during the plasma-based operation, a change that is to be made to a plasma source associated with the device fabrication process chamber based at least in part on the plasma characteristics; and
causing the determined change to be made to the plasma source associated with the device fabrication process chamber.

8. The method of claim 7, wherein the change to the plasma source comprises one or more of: a change to a coil position of a coil of the plasma source, a change in a current ratio delivered to two or more coils of the plasma source, or a change to gas flow parameters of one or more gases delivered to the plasma source.

9. The method of claim 1, further comprising identifying at least one change to be made to the device fabrication process chamber after the plasma-based operation has been completed for the wafer undergoing fabrication based at least in part on the plasma characteristics.

10. The method of claim 1, further comprising identifying at least one change that is to be made in a subsequent operation the wafer will undergo after completion of the plasma-based operation based at least in part on the plasma characteristics.

11. The method of claim 1, wherein the device fabrication process chamber comprises a multi-station fabrication tool, and wherein the wafer undergoing processing is residing in a first station of the multi-station fabrication tool.

12. The method of claim 11, further comprising processing the received signals to account for signals due to plasma in one or more stations of the multi-station fabrication tool other than the first station.

13. The method of claim 12, wherein processing the received signals to account for the signals due to plasma in the stations of the multi-station fabrication tool other than the first station comprises discarding pixels determined to be associated with the plasma in the stations other than the first station.

14. The method of claim 1, wherein determining the plasma characteristics comprises:
identifying one or more plasma regions in a frame of camera data associated with the received signals; and
determining the plasma characteristics for each of the one or more plasma regions.

15. The method of claim 14, wherein the one or more plasma regions comprise a region proximate to a showerhead of the device fabrication process chamber or a pedestal of the device fabrication process chamber.

16. The method of claim 14, wherein the one or more plasma regions are identified by performing edge detection on the frame of camera data.

17. The method of claim 14, wherein the one or more plasma regions are identified by providing the frame of camera data to a neural network.

18. The method of claim 1, further comprising triggering collection of signals by the one or more camera sensors via a trigger based on a synchronization of the trigger and plasma pulses of the plasma-based operation.

19. The method of claim 18, wherein the trigger is configured to trigger collection of the signals such that at least about three (3) frames are captured by the one or more camera sensors for a single plasma pulse of the plasma pulses.

20. The method of claim 19, further comprising integrating received signals corresponding to the at least about three (3) frames over a duration of the single plasma pulse to determine the plasma characteristics.

21. The method of claim 1, wherein the non-uniformity of the one or more wafer characteristics are determined by providing the plasma characteristics to a machine learning model.

22. The method of claim 1, wherein the plasma-based operation is a deposition process.

23. The method of claim 22, wherein the deposition process comprises: plasma-enhanced atomic layer deposition (PEALD), plasma-enhanced chemical vapor deposition (PECVD), or plasma-enhanced epitaxial growth.

24. A system comprising:
a process chamber configured to perform plasma-based operations on a wafer residing in the process chamber;
one or more optical access apertures that provide optical access into the process chamber;
one or more camera sensors optically coupled to the one or more optical access apertures; and
a controller configured to:
transmit signals from the one or more camera sensors during performance of a plasma-based operation to an edge device;
obtain information from the edge device, the information being indicative of plasma characteristics within the process chamber during performance of the plasma-based operation, wherein the plasma characteristics are indicative of a non-uniformity of one or more wafer characteristics of a wafer undergoing the plasma-based operation; and
cause at least one change in process conditions to be implemented in the process chamber based at least in part on the plasma characteristics.

25. The system of claim 24, further comprising one or more spectral filters configured to filter the signals from the one or more camera sensors based on wavelength.

26. The system of claim 24, further comprising a plasma source, and wherein the at least one change in process conditions comprises a change to the plasma source.

27. The system of claim 26, wherein the change to the plasma source comprises one or more of: a change to a coil position of a coil of the plasma source, a change in a current ratio delivered to two or more coils of the plasma source, or a change to gas flow parameters of one or more gases delivered to the plasma source.

28. The system of claim 24, wherein the process chamber comprises a showerhead, and wherein the at least one change comprises a change in at least one of a tilt or a vertical position of the showerhead.

29. The system of claim 24, wherein the process chamber comprises a multi-station fabrication tool, wherein the wafer is residing in a first station of the multi-station fabrication tool, and wherein the plasma characteristics received from the edge device account for plasma in other stations of the multi-station fabrication tool other than the first station.

30. The system of claim 24, wherein the controller is further configured to:
cause a plasma pulse to occur in association with the process chamber; and
cause the signals to be captured by the one or more camera sensors in a manner that is substantially synchronized with the plasma pulse.
